(19) United States
(12) Patent Application Publication
(10) Pub. No.: US 2026/0314214 A1
(43) Pub. Date: Oct. 8, 2026

(54) Display Substrate and Display Device

(71) Applicants: Chengdu BOE Optoelectronics Technology Co., Ltd., Chengdu, Sichuan (CN); BOE Technology Group Co., Ltd., Beijing (CN)

(72) Inventors: Fan HE, Beijing (CN); Shuang LI, Beijing (CN); Taofeng XIE, Beijing (CN)

(21) Appl. No.: 19/482,214

(22) PCT Filed: Feb. 14, 2025
(86) PCT No.: PCT/CN2025/077371

§ 371 Date: Nov. 6, 2025

(30) Foreign Application Priority Data
Mar. 15, 2024 (CN) 202410303553.8

(51) Int. Cl. H10K 59/131; H10K 77/10

(52) U.S. Cl. CPC H10K 59/1315; H10K 77/111

(57) ABSTRACT

A display substrate, including a display area and a first bezel area on one side of the display area in a first direction. The first bezel area includes a bending area and a first sub-area between the bending area and the display area. The display area is provided with a first center line extending in the first direction, and the first bezel area is provided with a second center line extending in the first direction. The distance between the first center line and the second center line is greater than 0. The display substrate further includes: a base substrate, a plurality of sub-pixels arranged on one side of the base substrate and located in the display area, a plurality of data lines; a plurality of first data fan-out lines located in the first sub-area, and a plurality of data bending lines located in the bending area.

### CROSS-REFERENCE TO RELATED APPLICATIONS

The present application is a U.S. National Phase Entry of International Application PCT/CN2025/077371 having an international filing date of Feb. 14, 2025, which claims the priority to Chinese Patent Application No. 202410303553.8, entitled “Display Substrate and Display Device”, filed on Mar. 15, 2024, the contents of the above-identified applications should be regarded as being incorporated herein by reference.

### TECHNICAL FIELD

The present disclosure relates to, but is not limited to, the field of display technologies, in particular to a display substrate and a display device.

### BACKGROUND

With rapid development of mobile devices and consumer electronics, there is an increasing demand for larger screen display areas and more portable designs. Traditional tablets and smartphones have a limited display screen size, and users desire a better visual experience with a larger display screen in daily use. In recent years, large foldable display screen technology has gradually attracted people's interest. By integrating the features of a flexible display screen and a foldable screen, this technology enables users to adjust the screen size through unfolding or folding actions, thus obtaining a larger display area while maintaining portability.

### SUMMARY

The following is a summary of subject matters described herein in detail. This summary is not intended to limit the protection scope of claims.

Embodiments of the present disclosure provide a display substrate and a display device.

In one aspect, an embodiment provides a display substrate, including a display area and a first bezel area located on a side of the display area in a first direction. The first bezel area includes a bending area, and a first sub-area located between the bending area and the display area. The display area has a first centerline extending in the first direction, and the first bezel area has a second centerline extending in the first direction. A distance between the first centerline and the second centerline is greater than 0. The display substrate includes a base substrate, a plurality of sub-pixels and a plurality of data lines provided on a side of the base substrate and located in the display area, a plurality of first data fan-out lines located in the first sub-area, and a plurality of data bending lines located in the bending area. The plurality of data lines are electrically connected to the plurality of sub-pixels, and configured to provide data signals to the plurality of sub-pixels. The plurality of first data fan-out lines are connected to the plurality of data lines. The plurality of data bending lines are connected to the plurality of first data fan-out lines. The plurality of data bending lines are symmetrically provided with respect to a third centerline, and the third centerline coincides with the first centerline, or coincides with the second centerline, or is located between the first centerline and the second centerline.

In some exemplary embodiments, the display substrate further includes a plurality of first power supply bending lines located in the bending area and extending in the first direction. The plurality of first power supply bending lines and the plurality of data bending lines are provided at intervals in a second direction, and the second direction intersects the first direction. The first bezel area further includes a second sub-area located on a side of the bending area away from the first sub-area. The display substrate further includes a first peripheral power supply line located in the first sub-area and a first power supply lead-out line located in the second sub-area. The first peripheral power supply line and the first power supply lead-out line are connected by the plurality of first power supply bent lines, and the plurality of first power supply bending lines are symmetrically provided with respect to the third centerline.

In some exemplary embodiments, the plurality of data bending lines include a first group of data bending lines, a second group of data bending lines, a third group of data bending lines, and a fourth group of data bending lines. The plurality of first power supply bending lines at least include a first group of first power supply bending lines, a second group of first power supply bending lines, and a third group of first power supply bending lines. The third group of data bending lines, the second group of first power supply bending lines, the first group of data bending lines, the first group of first power supply bending lines, the second group of data bending lines, the third group of first power supply bending lines, and the fourth group of data bending lines are sequentially provided in the second direction. The first group of data bending lines and the second group of data bending lines are symmetrically provided with respect to the third centerline, the third group of data bending lines and the fourth group of data bending lines are symmetrically provided with respect to the third centerline, the second group of first power supply bending lines and the third group of first power supply bending lines are symmetrically provided with respect to the third centerline, and the first group of first power supply bending lines are symmetrically provided with respect to the third centerline.

In some exemplary embodiments, a total length of the first group of first power supply bending lines in the second direction is greater than or equal to a total length of the second group of first power supply bending lines in the second direction and greater than or equal to a total length of the third group of first power supply bending lines in the second direction.

In some exemplary embodiments, the plurality of first power supply bending lines further include a fourth group of first power supply bending lines and a fifth group of first power supply bending lines. The fourth group of first power supply bending lines are located on a side of the third group of data bending lines away from the second group of first power supply bending lines, and the fifth group of first power supply bending lines are located on a side of the fourth group of data bending lines away from the third group of first power supply bending lines. The fourth group of first power supply bending lines and the fifth group of first power supply bending lines are symmetrically provided with respect to the third centerline.

In some exemplary embodiments, the display substrate further includes a plurality of second power supply bending lines located in the bending area and extending in the first direction. The plurality of second power supply bending lines are located on two sides of the plurality of data bending lines in the second direction. The display substrate further includes a second peripheral power supply line located in the first sub-area and a second power supply lead-out line located in the second sub-area. The second peripheral power supply line and the second power supply lead-out line are connected by the plurality of second power supply bending lines, and a second voltage signal transmitted by the second peripheral power supply line is different from a first voltage signal transmitted by the first peripheral power supply line. The plurality of second power supply bending lines are symmetrically provided with respect to the third centerline.

In some exemplary embodiments, the display substrate further includes a plurality of control bending lines located in the bending area and extending in the first direction. The plurality of control bending lines are located on two sides of the plurality of second power supply bending lines in the second direction, and the plurality of control bending lines are symmetrically provided with respect to the third centerline.

In some exemplary embodiments, the third centerline coincides with the second centerline. The first bezel area has a first bezel edge and a second bezel edge extending in the first direction. The first bezel edge and the second bezel edge are respectively located on two sides of traces of the bending area in the second direction, and the second direction intersects the first direction. A minimum distance between the traces of the bending area and the first bezel edge is a first edge distance, a minimum distance between the traces of the bending area and the second bezel edge is a second edge distance, and a ratio of the first edge distance to the second edge distance is 0.9 to 1.1.

In some exemplary embodiments, the third centerline is located between the first centerline and the second centerline, or the third centerline coincides with the first centerline. The first bezel area has a first bezel edge and a second bezel edge extending in the first direction. The first bezel edge and the second bezel edge are respectively located on two sides of traces of the bending area in the second direction, and the second direction intersects the first direction. A minimum distance between the traces of the bending area and the first bezel edge is a first edge distance, a minimum distance between the traces of the bending area and the second bezel edge is a second edge distance, and a ratio of the first edge distance to the second edge distance is greater than 1, or a ratio of the second edge distance to the first edge distance is greater than 1.

In some exemplary embodiments, at least one of the plurality of first data fan-out lines includes a first data extension segment and a second data extension segment connected to each other. The second data extension segment is connected to at least one of the plurality of data bending lines, and the second data extension segment is a straight line segment extending in the first direction. An extension direction of the first data extension segment intersects the first direction. The second centerline is located on a first side of the first centerline in a second direction, the second direction intersects the first direction, and the third centerline does not coincide with the first centerline. A length of a first data extension segment of at least one first data fan-out line close to the first centerline and located on a first side of the first centerline is greater than a length of a first data extension segment of at least one first data fan-out line close to the first centerline and located on a second side of the first centerline.

In some exemplary embodiments, the third centerline coincides with the first centerline, and the plurality of first data fan-out lines are symmetrically provided with respect to the third centerline.

In some exemplary embodiments, the first bezel area may further include a second sub-area located on a side of the bending area away from the first sub-area. The display substrate further includes a plurality of data lead-out lines located in the second sub-area. The plurality of data lead-out lines are connected to the plurality of data bending lines, and the plurality of data lead-out lines are symmetrically provided with respect to the third centerline.

In some exemplary embodiments, the display substrate further includes a plurality of power supply bending lines located in the bending area. The plurality of power supply bending lines and the plurality of data bending lines are provided at intervals in a second direction, and the second direction intersects the first direction. The plurality of power supply bending lines include a first group of power supply bending lines and a second group of power supply bending lines respectively located on two sides of the third centerline. A total length of the first group of power supply bending lines in the second direction is different from a total length of the second group of power supply bending lines in the second direction.

In some exemplary embodiments, the third centerline coincides with the first centerline. The first bezel area has a first bezel edge and a second bezel edge extending in the first direction. The first bezel edge and the second bezel edge are respectively located on two sides of traces of the bending area in the second direction, and the second direction intersects the first direction. A minimum distance between the traces of the bending area and the first bezel edge is a first edge distance, a minimum distance between the traces of the bending area and the second bezel edge is a second edge distance, and a ratio of the first edge distance to the second edge distance is 0.9 to 1.1.

In some exemplary embodiments, the third centerline coincides with the first centerline. The second centerline and the first group of power supply bending lines are located on a same side of the first centerline. A total length of the first group of power supply bending lines in the second direction is greater than a total length of the second group of power supply bending lines in the second direction.

In another aspect, an embodiment further provides a display device, including the aforementioned display substrate.

In another aspect, an embodiment provides a display substrate, including a display area and a first bezel area located on a side of the display area in a first direction. The first bezel area includes a bending area, and a first sub-area located between the bending area and the display area. The display area has a first centerline extending in the first direction, and the first bezel area has a second centerline extending in the first direction. A distance between the first centerline and the second centerline is greater than 0. The display substrate includes a base substrate, a plurality of sub-pixels and a plurality of data lines provided on a side of the base substrate and located in the display area, a plurality of first data fan-out lines located in the first sub-area, and a plurality of data bending lines located in the bending area. The plurality of data lines are electrically connected to the plurality of sub-pixels, and configured to provide data signals to the plurality of sub-pixels. The plurality of first data fan-out lines are connected to the plurality of data lines. The plurality of signal bending lines are located in a same conductive layer. The plurality of signal bending lines at least include a plurality of data bending lines. The plurality of data bending lines are connected to the plurality of first data fan-out lines, and the plurality of data bending lines are symmetrically provided with respect to the third centerline. The plurality of signal bending lines have a fourth centerline extending in the first direction. The fourth centerline coincides with the third centerline, or is located on a side of the third centerline close to the second centerline.

In some exemplary embodiments, the plurality of signal bending lines are symmetrically provided with respect to the fourth centerline. The third centerline and the fourth centerline coincide with the second centerline. The first bezel area has a first bezel edge and a second bezel edge extending in the first direction. The first bezel edge and the second bezel edge are respectively located on two sides of signal bending lines of the bending area in a second direction, and the second direction intersects the first direction. A minimum distance between the signal bending lines of the bending area and the first bezel edge is a first edge distance, a minimum distance between the signal bending lines of the bending area and the second bezel edge is a second edge distance, and a ratio of the first edge distance to the second edge distance is 0.9 to 1.1.

In some exemplary implementations, the plurality of signal bending lines are symmetrically provided with respect to the fourth centerline. The third centerline coincides with the fourth centerline and is located between the first centerline and the second centerline, or the third centerline and the fourth centerline coincide with the first centerline. The first bezel area has a first bezel edge and a second bezel edge extending in the first direction. The first bezel edge and the second bezel edge are respectively located on two sides of signal bending lines of the bending area in a second direction, and the second direction intersects the first direction. A minimum distance between the signal bending lines of the bending area and the first bezel edge is a first edge distance, a minimum distance between the signal bending lines of the bending area and the second bezel edge is a second edge distance, and a ratio of the first edge distance to the second edge distance is greater than 1, or a ratio of the second edge distance to the first edge distance is greater than 1.

In some exemplary embodiments, the plurality of signal bending lines are provided asymmetrically about the fourth centerline. The fourth centerline coincides with the second centerline, and the third centerline coincides with the first centerline. The first bezel area has a first bezel edge and a second bezel edge extending in the first direction. The first bezel edge and the second bezel edge are respectively located on two sides of signal bending lines of the bending area in a second direction, and the second direction intersects the first direction. A minimum distance between the signal bending lines of the bending area and the first bezel edge is a first edge distance, a minimum distance between the signal bending lines of the bending area and the second bezel edge is a second edge distance, and a ratio of the first edge distance to the second edge distance is 0.9 to 1.1.

Other features and advantages of the present application will be set forth in the specification which follows, and in part will become apparent from the specification, or may be learned by practice of the present application. Other advantages of the present application may be achieved and obtained through solutions described in the specification and drawings.

### BRIEF DESCRIPTION OF DRAWINGS

Accompanying drawings are intended to provide an understanding of technical solutions of the present application and constitute a part of the specification, and are used to explain the technical solutions of the present application together with embodiments of the present application, and do not constitute limitations on the technical solutions of the present application.

FIG. 1 is a schematic diagram of a display substrate according to at least one embodiment of the present disclosure.

FIG. 2A is a partial cross-sectional view of a display area of a display substrate according to at least one embodiment of the present disclosure.

FIG. 2B is another partial cross-sectional view of a display area of a display substrate according to at least one embodiment of the present disclosure.

FIG. 3 is a schematic partial structural view of a first bezel area according to at least one embodiment of the present disclosure.

FIG. 4 is a partially enlarged schematic view of an area S1 in FIG. 3.

FIG. 5 is another schematic partial structural view of a first bezel area according to at least one embodiment of the present disclosure.

FIG. 6 is a schematic diagram of partial traces in a first bezel area according to at least one embodiment of the present disclosure.

FIG. 7 is another partial view of a first bezel area according to at least one embodiment of the present disclosure.

FIG. 8 is another partial view of a first bezel area according to at least one embodiment of the present disclosure.

FIG. 9 is a partially enlarged schematic view of an area S2 in FIG. 8.

FIG. 10 is another partial view of a first bezel area according to at least one embodiment of the present disclosure.

FIG. 11 is a partially enlarged schematic view of an area S3 in FIG. 10.

FIG. 12 is another partial view of a first bezel area according to at least one embodiment of the present disclosure.

FIG. 13 is a partially enlarged schematic view of an area S4 in FIG. 12.

FIG. 14 is another partial view of a first bezel area according to at least one embodiment of the present disclosure.

FIG. 15 is another schematic diagram of a display substrate according to at least one embodiment of the present disclosure.

FIG. 16 is a schematic diagram of a display device according to at least one embodiment of the present disclosure.

### DETAILED DESCRIPTION

The embodiments of the present disclosure will be described below with reference to the drawings in detail. Implementations may be implemented in multiple different forms. Those of ordinary skills in the art may easily understand such a fact that modes and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third” and the like in the specification are set not to form limits in numbers but only to avoid confusion between constituent elements. In the present disclosure, “plurality” represents two or more than two.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements are changed as appropriate according to directions of the constituent elements described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, it may be a fixed connection, a detachable connection, or an integral connection; it may be a mechanical connection or a connection; it may be a direct connection, an indirect connection through a middleware, or an internal communication between two elements. Those of ordinary skills in the art may understand meanings of the aforementioned terms in the present disclosure according to situations.

In the specification, an “electrical connection” includes a case that constituent elements are connected together through an element with a certain electrical action. The “element with a certain electrical effect” is not particularly limited as long as electrical signals between the connected constituent elements can be transmitted. Examples of the “element with a certain electrical effect” not only include an electrode and a wiring, but also include a switching element such as a transistor, a resistor, an inductor, a capacitor, and other elements with a plurality of functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In addition, the gate electrode may also be referred to as a control electrode.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a circle, oval, triangle, rectangle, trapezoid, pentagon, or hexagon, or the like is not strictly defined, but may be an approximate circle, oval, triangle, rectangle, trapezoid, pentagon, or hexagon, or the like. Some small deformations due to tolerances may exist, for example, chamfers, arc edges, and deformations may exist.

In the present disclosure, “about” and “substantially” means that a boundary is not defined strictly and a case within a range of process and measurement errors is allowed. In the present disclosure, “substantially the same” refers to a case where numerical values differ by less than 10%. “Symmetry” in the present disclosure is a case where symmetry within a range of process and measurement errors is allowed.

In the present disclosure, “A extends in a B direction” means that A may include a main body portion and a secondary portion connected to the main body portion. The main body portion is a line, a line segment, or a strip-shaped body, the main body portion extends in the B direction, and a length of the main body portion extending in the B direction is greater than a length of the secondary portion extending in another direction. “A extends in the B direction” in the present disclosure always means “the main body portion of A extends in the B direction”.

In the present disclosure, “an orthographic projection of B is within a range of an orthographic projection of A” or “An orthographic projection of A contains an orthographic projection of B” means that a boundary of the orthographic projection of B falls within a range of a boundary of the orthographic projection of A, or the boundary of the orthographic projection of A is overlapped with the boundary of the orthographic projection of B. In the present disclosure, “a shape of A” refers to a shape of an orthographic projection of A on the base substrate.

In the present disclosure, a distance between A and B refers to a vertical distance or a minimum distance between A and B.

In some implementations, a secondary screen of a large foldable display screen needs to be designed with a cover plate. Usually, its shape is asymmetrically designed. As a result, a centerline of a display area and a centerline of a lower bezel are not on a same straight line, which puts forward new requirements for routing of signal traces of the lower bezel.

The present embodiment provides a display substrate, including a display area and a first bezel area located on a side of the display area in a first direction. The first bezel area includes a bending area and a first sub-area located between the bending area and the display area. The display area has a first centerline extending in a first direction, and the first bezel area has a second centerline extending in the first direction. A distance between the first centerline and the second centerline is greater than 0. The display substrate includes a base substrate, a plurality of sub-pixels and a plurality of data lines provided on a side of the base substrate and located in the display area, a plurality of first data fan-out lines located in the first sub-area, and a plurality of data bending lines located in the bending area. The plurality of data lines are electrically connected to the plurality of sub-pixels, and configured to provide data signals to the plurality of sub-pixels. The plurality of first data fan-out lines are connected to the plurality of data lines. The plurality of data bending lines are connected to the plurality of first data fan-out lines, and the plurality of data bending lines are symmetrically provided with respect to a third centerline. The third centerline coincides with the first centerline, or coincides with the second centerline, or is located between the first centerline and the second centerline. The third centerline, the first centerline, and the second centerline may extend in a same direction.

In the present embodiment, in a case where the first centerline of the display area and the second centerline of the first bezel area are not in a same straight line, the plurality of data bending lines in the bending area are symmetrically provided with respect to the third centerline, which may ensure consistency in density and film layer of the data bending lines on two sides of the third centerline, thereby ensuring bending effect. Further, the third centerline coincides with the first centerline or the second centerline, or is located between the first centerline and the second centerline, thereby mitigating a problem caused by signal trace differences due to asymmetric layout of the display substrate.

In some exemplary embodiments, the display substrate may further include a plurality of first power supply bending lines located in the bending area and extending in the first direction, and the plurality of first power supply bending lines and the plurality of data bending lines are provided at intervals in a second direction. The second direction intersects the first direction. For example, the second direction may be perpendicular to the first direction. The first bezel area may further include a second sub-area located on a side of the bending area away from the first sub-area. The display substrate may further include a first peripheral power supply line located in the first sub-area and a first power supply lead-out line located in the second sub-area, and the first peripheral power supply line and the first power supply lead-out line may be connected by the plurality of first power supply bending lines. The plurality of first power supply bending lines may be symmetrically provided with respect to the third centerline. In some examples, the first peripheral power supply line, the first power lead-out line, and the plurality of first power supply bending lines are electrically connected and configured to transmit a first voltage signal. In the present example, by symmetrically providing the plurality of first power supply bending lines in the bending area about the third centerline, consistency in density and film layer of the first power supply bending lines on two sides of the third centerline may be ensured, and consistency in transmission load of the first voltage signal on two sides of the third centerline may be facilitated.

In some exemplary embodiments, the display substrate may further include a plurality of second power supply bending lines extending in the first direction. The plurality of second power supply bending lines may be located on two sides of the plurality of data bending lines in the second direction. The display substrate may further include a second peripheral power supply line located in the first sub-area and a second power supply lead-out line located in the second sub-area. The second peripheral power supply line and the second power supply lead-out line may be connected by the plurality of second power supply bending lines, and a second voltage signal transmitted by the second peripheral power supply line is different from a first voltage signal transmitted by the first peripheral power supply line. The plurality of second power supply bending lines may be symmetrically provided with respect to the third centerline. In some examples, the first voltage signal may be greater than the second voltage signal. The first voltage signal may be configured to be supplied to a first power supply line to which a sub-pixel of the display area are connected, and the second voltage signal may be configured to be supplied to a cathode of a light-emitting element of a sub-pixel of the display area or a second power supply line to which a sub-pixel is connected. In the present example, by symmetrically providing the plurality of second power supply bending lines in the bending area about the third centerline, consistency in density and film layer of the second power supply bending lines on two sides of the third centerline may be ensured, and consistency in transmission load of the second voltage signal on two sides of the third centerline may be facilitated.

In some exemplary embodiments, the display substrate may further include a plurality of control bending lines located in the bending area and extending in the first direction. The plurality of control bending lines are located on two sides of the plurality of second power supply bending lines in the second direction, and the plurality of control bending lines may be symmetrically provided with respect to the third centerline. In some examples, the plurality of control bending lines may include a plurality of traces that supply a control signal (e.g., including a start signal, a clock signal, a voltage signal, etc.) to a gate drive circuit, and a trace that transmits a panel test signal. The gate drive circuit may be configured to provide a pixel control signal (including, for example, a scan signal, a reset signal, a light-emitting control signal, etc.) to a plurality of sub-pixels of the display area. In the present example, by symmetrically providing the plurality of control bending lines in the bending area about the third centerline, consistency in density and film layer of the control bending lines on two sides of the third centerline may be ensured, and consistency in transmission load of a same control signal on two sides of the third centerline may be facilitated.

In some exemplary embodiments, the third centerline may coincide with the second centerline. The first bezel area may have a first bezel edge and a second bezel edge extending in the first direction, and the first bezel edge and the second bezel edge may be respectively located on two sides of traces of the bending area in the second direction. A minimum distance between the traces of the bending area and the first bezel edge is a first edge distance, a minimum distance between the traces of the bending area and the second bezel edge is a second edge distance, and a ratio of the first edge distance to the second edge distance is 0.9 to 1.1. For example, the first edge distance may be equal to the second edge distance. The present example may ensure consistent distances between the traces of the bending area and edges of two sides of the display substrate, which facilitates arrangement of the traces in the bending area and ensures bending effect.

In some exemplary embodiments, the third centerline may be located between the first centerline and the second centerline, or the third centerline may coincide with the first centerline. The first bezel area may have a first bezel edge and a second bezel edge extending in the first direction, and the first bezel edge and the second bezel edge are respectively located on two sides of traces of the bending area in the second direction. A minimum distance between the traces of the bending area and the first bezel edge is a first edge distance, a minimum distance between the traces of the bending area and the second bezel edge is a second edge distance, and a ratio of the first edge distance to the second edge distance is greater than 1, or a ratio of the second edge distance to the first edge distance is greater than 1. In other words, the first edge distance is different from the second edge distance. In the present example, by adjusting a difference between the first edge distance and the second edge distance, it is beneficial to ensure symmetrical arrangement of the traces in the bending area, thereby reducing signal transmission differences between two sides of the second centerline in the first bezel area.

In some exemplary embodiments, the display substrate may include a plurality of power supply bending lines located in the bending area. The plurality of power supply bending lines and the plurality of data bending lines may be provided at intervals in the second direction. The plurality of power supply bending lines may include a first group of power supply bending lines and a second group of power supply bending lines respectively located on two sides of the third centerline, and a total length of the first group of power supply bending lines in the second direction may be different from a total length of the second group of power supply bending lines in the second direction. In some examples, a total length of a group of power supply bending lines in the second direction may include a sum of line widths of all power supply bending lines within the group of power supply bending lines, and spacings between adjacent power supply bending lines. In the present example, no additional traces are provided between the adjacent power supply bending lines. In the present example, symmetrical arrangement of the plurality of data bending lines may be ensured by adjusting a total length of one or more groups of power supply bending lines on two sides of the third centerline in the second direction.

In some examples, the third centerline may coincide with the first centerline, and the second centerline and the first group of power supply bending lines may be located on a same side of the first centerline. A total length of the first group of power supply bending lines in the second direction may be greater than a total length of the second group of power supply bending lines in the second direction. In the present example, trace arrangement in the first bezel area may be optimized by adjusting a length of the first group of power supply bending lines and the second group of power supply bending lines in the second direction.

The solution of the present embodiment will be illustrated below through some examples.

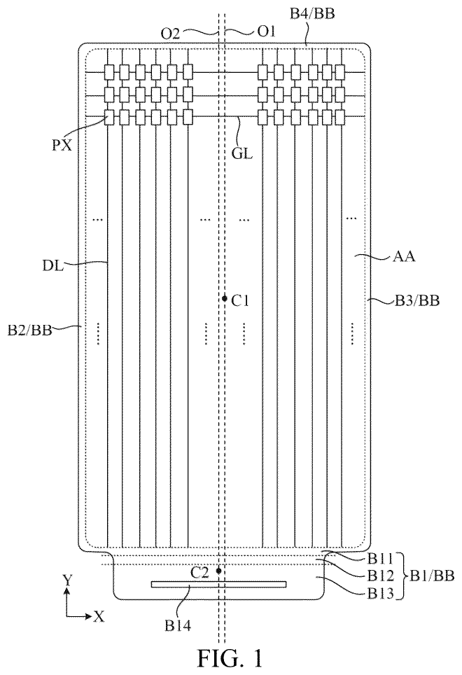

FIG. 1 is a schematic diagram of a display substrate according to at least one embodiment of the present disclosure. In some examples, as shown in FIG. 1, the display substrate may be in a shape of a closed polygon including linear sides. For example, the display substrate of the present example may be applied to a secondary screen of a large stack display product. The display substrate may include a display area AA and a bezel area BB located around the display area AA. For example, the display area AA may include a first display edge (lower display edge) and a second display edge (upper display edge) oppositely provided in a first direction Y, and a third display edge (left display edge) and a fourth display edge (right display edge) oppositely provided in a second direction X. The first display edge and the second display edge may be linear sides parallel to each other, and the third display edge and the fourth display edge may be linear sides parallel to each other. Adjacent linear sides may be connected through a curved edge (such as an arc-shaped edge).

In some examples, the bezel area BB may include a first bezel area B1 and a fourth bezel area B4 respectively located on two sides of the display area AA in a first direction Y, and a second bezel area B2 and a third bezel area B3 respectively located on the other two sides of the display area AA in a second direction X. The first bezel area B1 may be connected to the first display edge, the second bezel area B2 may be connected to the third display edge, the third bezel area B3 may be connected to the fourth display edge, and the fourth bezel area B4 may be connected to the second display edge. The first bezel area B1 may communicate with the second bezel area B2 and the third bezel area B3, the third bezel area B4 may communicate with the second bezel area B2 and the third bezel area B3, and the first bezel area B1, the second bezel area B2, the third bezel area B3, and the fourth bezel area B4 may surround the display area AA after communicating. For example, the first bezel area B1 may also be referred to as a lower bezel area of the display substrate, the second bezel area B2 may also be referred to as a left bezel area of the display substrate, the third bezel area B3 may also be referred to as a right bezel area of the display substrate, and the fourth bezel area B4 may also be referred to as an upper bezel area of the display substrate. However, the present embodiment is not limited thereto.

In some examples, the display area AA of the display substrate may at least include a plurality of sub-pixels PX, a plurality of gate lines GL, and a plurality of data lines DL. The plurality of gate lines GL may extend in the second direction X and be arranged in the first direction Y, and the plurality of data lines DL may extend in the first direction Y and be arranged in the second direction X. The plurality of data lines DL may be electrically connected to the plurality of sub-pixels PX, and the plurality of data lines DL may be configured to provide data signals to the plurality of sub-pixels PX. The plurality of gate lines GL may be electrically connected to the plurality of sub-pixels PX, and the plurality of gate lines GL may be configured to provide pixel control signals to the plurality of sub-pixels PX. For example, the pixel control signals may include a scan signal, or may include a scan signal and a light emitting control signal, or may include a scan signal, a reset control signal, and a light emitting control signal.

In some examples, the second direction X may be an extension direction (e.g., a row direction) of the gate lines GL within the display area AA, and the first direction Y may be an extension direction (for example, a column direction) of the data lines DL within the display area AA. The first direction Y and the second direction X may intersect with each other, for example, they may be perpendicular to each other.

In some examples, one pixel unit of the display area AA may include three sub-pixels, which may be a first sub-pixel emitting light of a first color (e.g., red light), a second sub-pixel emitting light of a second color (e.g., green light), and a third sub-pixel emitting light of a third color (e.g., blue light), respectively. However, the present embodiment is not limited thereto. In some examples, one pixel unit may include four sub-pixels, which may be a sub-pixel emitting red light, a sub-pixel emitting green light, a sub-pixel emitting blue light, and a sub-pixel emitting white light, respectively. For another example, one pixel unit may include four sub-pixels, which may include one sub-pixel emitting red light, one sub-pixel emitting blue light, and two sub-pixels emitting green light.

In some examples, one sub-pixel may include a pixel circuit and a light emitting element electrically connected to the pixel circuit. The pixel circuit may include a plurality of transistors and at least one capacitor. For example, the pixel circuit may have a 3T1C, 4T1C, 5T1C, 5T2C, 6T1C, 7T1C, or 8T1C structure. In the aforementioned circuit structures, T refers to a thin film transistor, C refers to a capacitor, a digit before T represents a quantity of thin film transistors in the circuit, and a digit before C represents a quantity of capacitors in the circuit. In some examples, the plurality of transistors in the pixel circuit may include a P-type transistor and an N-type transistor. In other examples, the plurality of transistors in the pixel circuit may be P-type transistors, or may be N-type transistors. Using a same type of transistors in the pixel circuit may simplify a process flow, reduce a process difficulty of the display substrate, and improve a yield of products.

In some examples, a shape of the light emitting element of the sub-pixel may be a rectangle, a rhombus, a pentagon, or a hexagon. When one pixel unit includes three sub-pixels, light emitting elements of the three sub-pixels may be arranged side by side horizontally, side by side vertically, or in a manner like a Chinese character “ ”. When one pixel unit includes four sub-pixels, light emitting elements of the four sub-pixels may be arranged side by side horizontally, side by side vertically, or in a manner of a square. However, the present embodiment is not limited thereto.

In some examples, the light emitting element may be any one of a Light Emitting Diode (LED), an Organic Light Emitting Diode (OLED), a Quantum dot Light Emitting Diode (QLED), a micro LED (including: mini-LED or micro-LED), and the like. For example, the light emitting element may be an OLED, and the light emitting element may emit red light, green light, blue light, or white light, or the like under drive of a pixel circuit corresponding to the light emitting element. A color of light emitted by the light emitting element may be determined as needed. In some examples, the light emitting element may include an anode, a cathode, and an organic emitting layer located between the anode and the cathode. The anode of the light emitting element may be electrically connected to a corresponding pixel circuit. However, the present embodiment is not limited thereto.

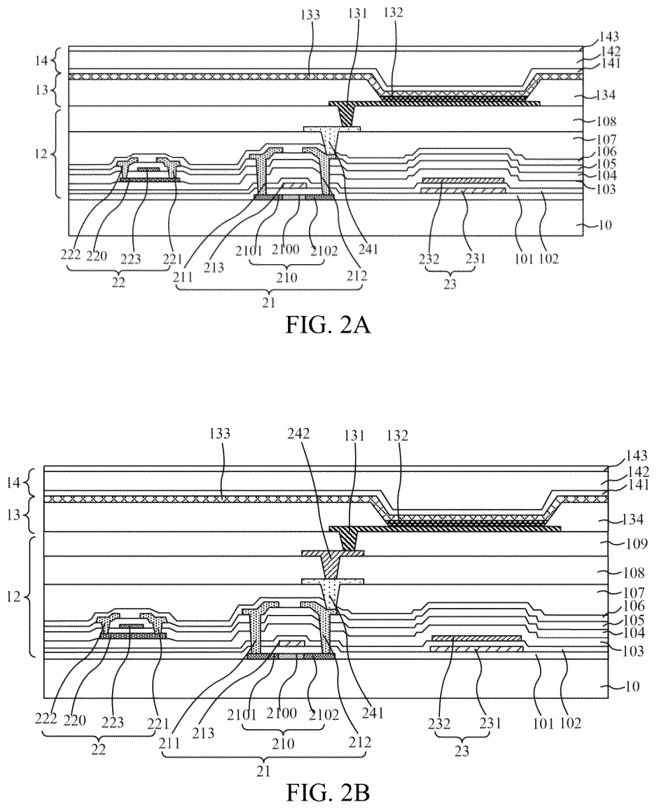

FIG. 2A is a partial sectional view of a display area of a display substrate according to at least one embodiment of the present disclosure. FIG. 2A is illustrated by taking a structure of one sub-pixel of the display area as an example. In the present example, the transistor types of the plurality of pixel transistors in the pixel circuit may be different, and may include, for example, low-temperature polysilicon thin film transistors and oxide thin film transistors.

In some examples, as shown in FIG. 2A, in a direction perpendicular to the display substrate, the display area of the display substrate may include a base substrate 10, and a circuit structure layer 12, a light emitting structure layer 13, and an encapsulation structure layer 14 which are provided sequentially on the base substrate 10. The circuit structure layer 12 may at least include pixel circuits of a plurality of sub-pixels, and a pixel circuit of each sub-pixel may include a plurality of transistors and at least one capacitor. The light emitting structure layer 13 may at least include light emitting elements of a plurality of sub-pixels. In some examples, the display panel may further include a touch structure layer located on a side of the encapsulation structure layer away from the base substrate. For example, the touch structure layer may include at least one touch conductive layer.

In some examples, FIG. 2A illustrates one first transistor 21, one second transistor 22, and one capacitor 23 included in each sub-pixel as an example. Transistor types of the first transistor 21 and the second transistor 22 may be different. For example, the first transistor 21 may be a low temperature polysilicon thin film transistor, and the second transistor 22 may be an oxide thin film transistor.

In some examples, the circuit structure layer 12 of the display area may include: a first semiconductor layer, a first gate metal layer, a second gate metal layer, a second semiconductor layer, a third gate metal layer, a first source-drain metal layer, and a second source-drain metal layer, which are provided on the base substrate 10. A first insulation layer 101 may be provided between the first semiconductor layer and the first gate metal layer, a second insulation layer 102 may be provided between the first gate metal layer and the second gate metal layer, a third insulation layer 103 may be provided between the second gate metal layer and the second semiconductor layer, a fourth insulation layer 104 may be provided between the second semiconductor layer and the third gate metal layer, a fifth insulation layer 105 may be provided between the third gate metal layer and the first source-drain metal layer, a sixth insulation layer 106 (which may also be referred to as a passivation (PVX) layer) and a seventh insulation layer 107 (which may also be referred to as a first planarization (PLN) layer) may be provided between the first source-drain metal layer and the second source-drain metal layer, the seventh insulation layer 107 may be located on a side of the sixth insulation layer 106 away from the base substrate 10, and an eighth insulation layer 108 (which may also be referred to as a second planarization layer) may be provided on a side of the second source-drain metal layer away from the base substrate 10. Herein, the first insulation layer 101, the second insulation layer 102, the third insulation layer 103, the fourth insulation layer 104, the fifth insulation layer 105, and the sixth insulation layer 106 may be inorganic insulation layers, and the seventh insulation layer 107 and the eighth insulation layer 108 may be organic insulation layers. However, the present embodiment is not limited thereto. In other examples, a side of the first semiconductor layer close to the base substrate may also be provided with a buffer layer, which may prevent harmful substances in the base substrate from intruding into interior of the display substrate, and may also increase adhesion of a film layer in the display substrate on the base substrate. In other examples, a Bottom Shielding Metal (BSM) layer may also be provided on a side of the buffer layer close to the base substrate, and the bottom shielding metal layer may be configured to at least partially cover an active layer of a transistor of a pixel circuit to avoid an influence of external light on performance of the transistor. In other examples, the sixth insulation layer may be omitted between the first source-drain metal layer and the second source-drain metal layer, and only the seventh insulation layer may be provided between the first source-drain metal layer and the second source-drain metal layer.

In some examples, as shown in FIG. 2A, the first semiconductor layer of the display area may at least include a first active layer 210 of the first transistor 21. The first active layer 210 of the first transistor 21 may include a first region 2101, a second region 2102, and a channel region 2100 located between the first region 2101 and the second region 2102. The first gate metal layer may at least include a first gate 213 of the first transistor 21, and a first plate 231 of the capacitor 23. An orthographic projection of the first gate 213 of the first transistor 21 on the base substrate 10 may cover an orthographic projection of the channel region 2100 of the first active layer 210 on the base substrate 10. The second gate metal layer may at least include a second electrode plate 232 of the capacitor 23. Orthographic projections of the second electrode plate 232 and the first electrode plate 231 of the capacitor 23 on the base substrate 10 may be at least partially overlapped, for example, the two may coincide. The second semiconductor layer may at least include a second active layer 220 of the second transistor 22. The third gate metal layer may at least include a second gate 223 of the second transistor 22. An orthographic projection of the second gate 223 of the second transistor 22 on the base substrate 10 may partially overlap with an orthographic projection of the second active layer 220 on the base substrate 10.

In some examples, as shown in FIG. 2A, the first source-drain metal layer may include at least a first source electrode 211 and a first drain electrode 212 of the first transistor 21, and a second source electrode 221 and a second drain electrode 222 of the second transistor 22. The fifth insulation layer 105 may be provided with a plurality of pixel vias (including, for example, a first pixel via, a second pixel via, a third pixel via, and a fourth pixel via) in the display area, and the fifth insulation layer 105, the fourth insulation layer 104, the third insulation layer 103, the second insulation layer 102, and the first insulation layer 101 within the first pixel via may be removed to expose at least part of a surface of the first region 2101 of the first active layer 210; the fifth insulation layer 105, the fourth insulation layer 104, the third insulation layer 103, the second insulation layer 102, and the first insulation layer 101 within the second pixel via may be removed to expose at least part of a surface of the second region 2102 of the first active layer 210. The fifth insulation layer 105 and the fourth insulation layer 104 within the third pixel via and the fourth pixel via may be removed to expose at least part of the surface of both ends of the second active layer 220. The first source 211 of the first transistor 21 may be electrically connected to the first region 2101 of the first active layer 210 through the first pixel via, and the first drain 212 may be electrically connected to the second region 2102 of the first active layer 210 through the second pixel via. The second source 221 of the second transistor 22 may be electrically connected to one end of the second active layer 220 through the third pixel via, and the second drain 222 of the second transistor 22 may be electrically connected to the other end of the second active layer 220 through the fourth pixel via. The second source-drain metal layer may at least include a first transfer electrode 241. The first transfer electrode 241 may be electrically connected to the first drain electrode 212 of the first transistor 21 of the pixel circuit through the fifth pixel via opened in the sixth insulation layer 106 and the seventh insulation layer 107. In the present example, an electrical connection between the pixel circuit and the light emitting element may be achieved through the first transfer electrode 241.

In some examples, a plurality of gate lines of the display substrate may include a first scan line, a second scan line, a first reset control line, a second reset control line, and a light emitting control line. The plurality of gate lines may, for example, be located in the first gate metal layer and the third gate metal layer. For example, the first scan line, the first reset control line, the second reset control line, and the light emitting control line may be located in the first gate metal layer, and the second scan line may be located in the third gate metal layer. A plurality of data lines may, for example, be located in the second source-drain metal layer, and a first power supply line of the display area may, for example, be located in the second source-drain metal layer. However, the present embodiment is not limited thereto.

In some examples, as shown in FIG. 2A, the light emitting structure layer 13 may include a pixel definition layer 134 and a plurality of light emitting elements. For example, each light emitting element may include a first electrode 131, an organic emitting layer 132, and a second electrode 133 which are stacked. The first electrode 131 of the light emitting element may be an anode, the first electrode 131 may be provided on the eighth isolation layer 108 and electrically connected to the first transfer electrode 241 through the sixth pixel via opened in the eighth insulation layer 108. The pixel definition layer 134 is provided on the first electrode 131 and the eighth insulation layer 108, and the pixel definition layer 134 may be provided with a plurality of pixel openings, one pixel opening may expose at least portion of a surface of a corresponding first electrode 131. At least portion of the organic emitting layer 132 may be provided within one pixel opening and connected to a corresponding first electrode 131. The second electrode 133 may be provided on the organic emitting layer 132 and be connected to the organic emitting layer 132. The organic emitting layer 132 may emit light of a corresponding color under drive of the first electrode 131 and the second electrode 133.

In some examples, the organic emitting layer 132 of the light emitting element may include an Emitting Layer (EML), and include one or more film layers of a Hole Injection Layer (HIL), a Hole Transport Layer (HTL), a Hole Block Layer (HBL), an Electron Block Layer (EBL), an Electron Injection Layer (EIL), and an Electron Transport Layer (ETL). Under drive of voltages of the first electrode 131 and the second electrode 133, light may be emitted according to a required gray scale, in virtue of light emitting characteristics of an organic material.

In some examples, emitting layers of light emitting elements of different colors may be different. For example, a red light emitting element includes a red emitting layer, a green light emitting element includes a green emitting layer, and a blue light emitting element includes a blue emitting layer. In order to reduce a process difficulty and improve a yield, a common layer may be adopted for a hole injection layer and a hole transport layer located at one side of an emitting layer, and a common layer may be adopted for an electron injection layer and an electron transport layer located at the other side of the emitting layer. In some examples, any one or more layers of the hole injection layer, the hole transport layer, the electron injection layer, and the electron transport layer may be made through one process (one evaporation process or one inkjet printing process), and isolation may be achieved by means of a formed film layer surface segment difference or by means of a surface treatment. For example, any one or more of hole injection layers, hole transport layers, electron injection layers, and electron transport layers corresponding to adjacent sub-pixels may be isolated. In some examples, the organic emitting layer may be prepared and formed through evaporation using a Fine Metal Mask (FMM) or an open mask, or prepared and formed using an inkjet process.

In some examples, as shown in FIG. 2A, the encapsulation structure layer 14 may include a first encapsulation layer 141, a second encapsulation layer 142, and a third encapsulation layer 143 which are stacked. Herein, the first encapsulation layer 141 and the third encapsulation layer 143 may be made of an inorganic material such as silicon nitride, silicon oxide, and silicon oxynitride, the inorganic material has high compactness and may prevent intrusion of water, oxygen, and the like. The second encapsulation layer 142 may be provided between the first encapsulation layer 141 and the third encapsulation layer 143 to ensure that external moisture cannot enter the light emitting element. The second encapsulation layer 142 may be made of an organic material, which, for example, may be a polymer material containing a desiccant, a polymer material capable of blocking moisture, or the like, or may be a polymer resin or the like to flatten a surface of the display substrate, and may relieve stress of the first encapsulation layer 141 and the third encapsulation layer 143, and may further include a water-absorbing material such as a desiccant to absorb substances such as water and oxygen entering the interior. However, the present embodiment is not limited thereto. For example, an encapsulation structure layer may be of a five-layer stacked structure of inorganic/organic/inorganic/organic/inorganic.

FIG. 2B is another partial sectional view of a display area of a display substrate according to at least one embodiment of the present disclosure. In some examples, as shown in FIG. 2B, a circuit structure layer 12 of the display area may include a first semiconductor layer, a first gate metal layer, a second gate metal layer, a second semiconductor layer, a third gate metal layer, a first source-drain metal layer, a second source-drain metal layer, and a third source-drain metal layer provided on the base substrate 10. An eighth insulation layer 108 may be provided between the second source-drain metal layer and the third source-drain metal layer, and a ninth insulation layer 109 (which may also be referred to as a third planarization layer) may be provided on a side of the third source-drain metal layer away from the base substrate. The ninth insulation layer 109 may be an organic insulation layer. The third source-drain metal layer may include at least a second transfer electrode 242, which may be connected to a first transfer electrode 241 on the second source-drain metal layer. In the present example, an electrical connection between the pixel circuit and a first electrode 131 of a light emitting element may be achieved through the first transfer electrode 241 and the second transfer electrode 242. Rest of a structure of the display area of the display substrate of the present example may be referred to the description of the embodiment shown in FIG. 2A, which will not be repeated here.

In some examples, as shown in FIG. 1, the first bezel area B1 may include a first sub-area B11, a bending area B12, and a second sub-area B13 sequentially provided in a direction away from the display area AA. The bending area B12 may be communicated with the first sub-area B11 and the second sub-area B13. The first sub-area B11 may be communicated with the second bezel area B2 and the third bezel area B3, and connected to the display area AA. The first sub-area B11 may also be referred to as a first fan-out area. The bending area B12 may be configured to enable the second sub-area B13 to be bent to a back of the display area AA. A plurality of signal bending lines may be provided in the bending area B12 to achieve electrical connection between traces transmitting a same signal in the first sub-area B11 and the second sub-area B13. The second sub-area B13 may at least include a first signal access area B14. The first signal access area B14 may be provided with a plurality of first contact pads, which may be configured to be connected to a drive integrated circuit (IC).

In some examples, the second sub-area B13 may include a first signal access area B14, a circuit setting area located between the bending area B12 and the first signal access area B14, a second fan-out area located between the bending area B12 and the circuit setting area, a third fan-out area located between the circuit setting area and the first signal access area B14, and a second signal access area located on a side of the first signal access area B14 away from the bending area B12. Here, the second fan-out area, the circuit setting area, the third fan-out area, the first signal access area B14, and the second signal access area may be sequentially provided in a direction away from the bending area B12. The circuit setting area may be at least provided with a plurality of test circuits arranged in the second direction X, or provided with a plurality of test circuits, a plurality of electrostatic discharge circuits located on a side of the plurality of test circuits close to the bending area B12, and a plurality of data selection circuits located on a side of the plurality of test circuits away from the bending area B12. The second signal access area may be provided with a plurality of second contact pads, and the plurality of second contact pads may be configured to be bonded and connected to an external Flexible Printed Circuit board (FPC). At least one first contact pad in the first signal access area B14 and at least one second contact pad in the second signal access area may be connected by a lead-out connection line. The present embodiment is not limited thereto. In other examples, the second sub-area B13 may include a second fan-out area, a first signal access area B14, and a second signal access area sequentially provided in a direction away from the bending area B12.

In some examples, as shown in FIG. 1, the display area AA may have a first centerline O1 extending in the first direction Y, the first centerline O1 passing through a center point C1 of the display area AA. For example, a distance between the first display edge and the center point C1 and a distance between the second display edge and the center point C1 may be the same; and a distance between the third display edge and the center point C1 and a distance between the fourth display edge and the center point C1 may be the same. The first centerline O1 may divide the display area AA into a first sub-display area and a second sub-display area arranged in the second direction X. The plurality of data lines DL in the display area AA may include a first group of data lines located in the first sub-display area and a second group of data lines located in the second sub-display area. A quantity of data lines in the first group of data lines and a quantity of data lines in the second group of data lines may be the same. For example, the first group of data lines and the second group of data lines may be symmetrically provided with respect to the first centerline O1. However, the present embodiment is not limited thereto.

In the present example, two groups of traces being symmetrically provided with respect to a centerline means that quantities of traces in the two groups of traces are the same, the traces in the two groups of traces are symmetrically provided with respect to the centerline, the traces symmetrically provided with respect to the centerline in the two groups of traces have a same line width, and spacing lengths between adjacent traces are the same. A group of traces being symmetrically provided with respect to a centerline means that the group of traces may be divided into two portions located on two sides of the centerline and provided symmetrically, and the two portions include a same quantity of traces; or, the group of traces may be divided into two portions located on two sides of the centerline and provided symmetrically, and a trace passing through the centerline, and the two portions include a same quantity of traces.

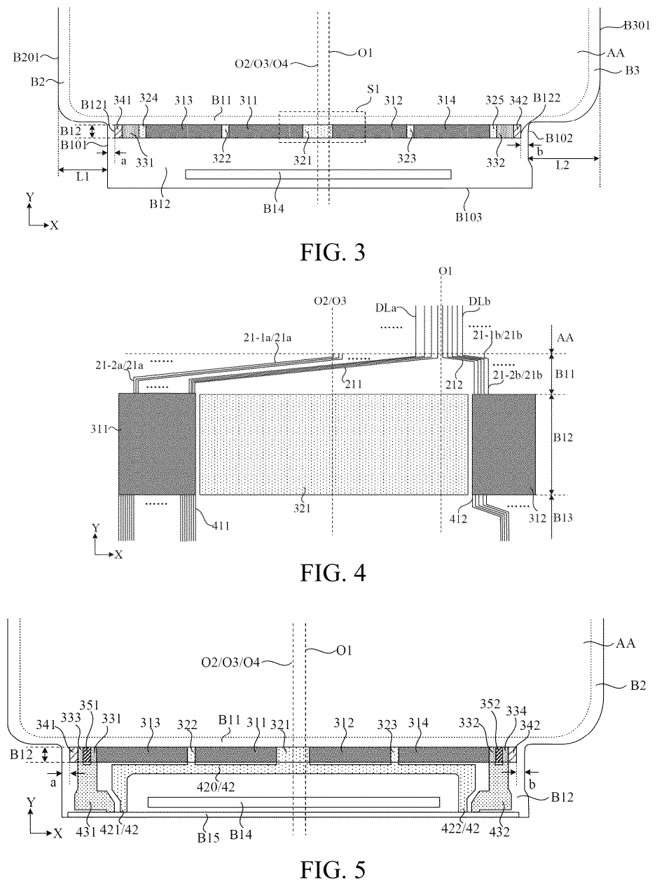

FIG. 3 is a schematic partial structural view of a first bezel area according to at least one embodiment of the present disclosure. In some examples, as shown in FIGS. 1 and 3, the bezel area BB may at least include a first bezel edge B101 and a second bezel edge B102 of the first bezel area B1 opposite to each other in the second direction X, and a third bezel edge B201 and a fourth bezel edge B301 opposite to each other in the second direction X. The first bezel edge B101 and the second bezel edge B102 may extend substantially in the first direction Y. For example, the first bezel edge B101 and the second bezel edge B102 may be linear edges parallel to each other. The first bezel edge B101 is, for example, a left edge of the first bezel area B1, and the second bezel edge B102 is, for example, a right edge of the first bezel area B1. The third bezel edge B201 may be a left edge of the second bezel area B2, and a right edge of the second bezel area B2 is connected to the third display edge of the display area AA. The fourth bezel edge B202 may be a right edge of the third bezel area B3, and a left edge of the third bezel area B3 is connected to the fourth display edge of the display area AA. The third bezel edge B201 and the third display edge may be linear edges parallel to each other, and the fourth bezel edge B301 and the fourth display edge may be linear edges parallel to each other. The first bezel edge B101 and the third bezel edge B201 may be connected by a curved bezel edge, and the third bezel edge B201 and the fourth bezel edge B202 may be connected by a curved bezel edge. The first bezel edge B101 and the second bezel edge B102 may be connected by a fifth bezel edge B103 extending in the second direction X, and the third bezel edge B201 and the fourth bezel edge B301 may be connected by an edge of the fourth bezel area B4 away from the display area AA.

In some examples, as shown in FIGS. 1 and 3, the first bezel area B1 may have a second centerline O2 extending in the first direction Y, the second centerline O2 passing through a center point C2 of the first bezel area B1. A distance between the first bezel edge B101 and the center point C2 may be substantially the same as a distance between the second bezel edge B102 and the center point C2, and a distance between the first display edge and the center point C2 may be substantially the same as a distance between the fifth bezel edge B103 and the center point C2. The second centerline O2 may divide the first bezel area B1 into a lower left bezel region and a lower right bezel region arranged in the second direction X. The second centerline O2 may pass through a center point of the first signal access area B14. In other words, the centerline of the first signal access area B14 extending in the first direction Y may coincide with the second centerline O2. However, the present embodiment is not limited thereto. In other examples, a centerline of the first signal access area B14 extending in the first direction Y may coincide with the first centerline O1.

In some examples, the first bezel edge B101 and the third bezel edge B201 have a first distance L1 in the second direction X, and the second bezel edge B102 and the fourth bezel edge B301 have a second distance L2 in the second direction X. The first distance L1 is not equal to the second distance L2. For example, the first distance L1 may be smaller than the second distance L2. An entire display substrate of the present example has an asymmetric structure, and the second centerline O2 of the first bezel area B1 does not coincide with the first centerline O1 of the display area AA. For example, the second centerline O2 may be located on a side of the first centerline O1 in an opposite direction of the second direction X. In other examples, when the first distance L1 is greater than the second distance L2, the second centerline O2 may be located on a side of the first centerline O1 in the second direction X.

In some examples, as shown in FIG. 3, the bending area B12 may be provided with a group of signal bending lines including a plurality of signal bending lines (e.g., including a plurality of data bending lines, a plurality of first power supply bending lines, a plurality of second power supply bending lines, and a plurality of control bending lines). The plurality of signal bending lines may extend in the first direction Y and be arranged in the second direction X. An orthographic projection of the group of signal bending lines on the base substrate may have a fourth centerline O4 extending in the first direction Y. The group of signal bending lines may be symmetrically provided with respect to the fourth centerline O4. For example, the fourth centerline O4 may coincide with the third centerline O3. The third centerline O3 passes through a center point of an area corresponding to the orthographic projection of the group of signal bending lines on the base substrate. For example, the area corresponding to the orthographic projection of the group of signal bending lines on the base substrate may be substantially rectangular. The orthographic projection of the group of signal bending lines on the base substrate may have a first trace edge B121 and a second trace edge B122. The first trace edge B121 may be an edge of an edge trace (for example, a leftmost trace, such as a control bending line of the edge) of the group of signal bending lines close to the first bezel edge B101, and the second trace edge B122 may be an edge an edge trace (e.g., a rightmost trace, such as a control bending line of the edge) of the group of signal bending lines close to the second bezel edge B102. Both the first trace edge B121 and the second trace edge B122 may extend substantially in the first direction Y. A distance between the first trace edge B121 and the third centerline O3 and a distance between the second trace edge B122 and the third centerline O3 may be substantially the same. The distance between the first trace edge B121 and the third centerline O3 may be a sum of line widths and spacings of a plurality of signal bending lines located on a side of the third centerline O3 in the opposite direction of the second direction X. The distance between the second edge trace B122 and the third centerline O3 may be a sum of line widths and spacings of a plurality of signal bending lines located on a side of the third centerline O3 in the second direction X.

In some examples, as shown in FIG. 3, the bending area B12 may be provided with four groups of data bending lines (including, for example, a first group of data bending lines 311, a second group of data bending lines 312, a third group of data bending lines 313, and a fourth group of data bending lines 314), five groups of first power supply bending lines (including, for example, a first group of first power supply bending lines 321, a second group of first power supply bending lines 322, a third group of first power supply bending lines 323, a fourth group of first power supply bending lines 324, and a fifth group of first power supply bending lines 325), two groups of second power supply bending lines (including, for example, a first group of second power supply bending lines 331 and a second group of second power supply bending lines 332), and two groups of control bending lines (including, for example, a first group of control bending lines 341 and a second group of control bending lines 342). In FIG. 3, each group of data bending lines, each group of first power supply bending lines, each group of second power supply bending lines, each group of control bending lines, and each group of touch bending lines in the bending area B12 are schematically illustrated in an integrated manner.

In some examples, each group of data bending lines may include a plurality of data bending lines arranged in the second direction X. The plurality of data bending lines may have a same line width, and spacings between adjacent data bending lines may be the same. Each group of first power supply bending lines may include a plurality of first power supply bending lines arranged in the second direction X. The plurality of first power supply bending lines may have a same line width, and spacings between adjacent first power supply bending lines may be the same. A plurality of first power supply bending lines within a same group of first power supply bending lines may be connected to each other. Each group of second power supply bending lines may include a plurality of second power supply bending lines arranged in the second direction X. The plurality of second power supply bending lines may have a same line width, and spacings between adjacent second power supply bending lines may be the same. A plurality of second power supply bending lines within a same group of second power supply bending lines may be connected to each other. Each group of control bending lines may include a plurality of control bending lines arranged in the second direction X. Control bending lines transmitting a same signal may have a same line width, and spacings between adjacent control bending lines may be the same.

In some examples, the plurality of signal bending lines in the bending area B12 may be located in a same conductive layer, for example, may be located in a second source-drain metal layer. However, the present embodiment is not limited thereto. For example, the plurality of signal bending lines may be located in a first source-drain metal layer, or may be located in a third source-drain metal layer.

In some examples, the first group of control bending lines 341, the first group of second power supply bending lines 331, the fourth group of first power supply bending lines 324, the third group of data bending lines 313, the second group of first power supply bending lines 322, the first group of data bending lines 311, the first group of first power supply bending lines 321, the second group of data bending lines 312, the third group of first power supply bending lines 323, the fourth group of data bending lines 314, the fifth group of first power supply bending lines 325, the second group of second power supply bending lines 332, and the second group of control bending lines 342 may be sequentially arranged in the second direction X.

In some examples, the plurality of data bending lines may be symmetrically provided with respect to the third centerline O3. A quantity of data bending lines in the first group of data bending lines 311 and a quantity of data bending lines in the second group of data bending lines 312 may be the same, and the first group of data bending lines 311 and the second group of data bending lines 312 may be symmetrically provided with respect to the third centerline O3. A quantity of data bending lines in the third group of data bending lines 313 and a quantity of data bending lines in the fourth group of data bending lines 314 may be the same, and the third group of data bending lines 313 and the fourth group of data bending lines 314 may be symmetrically provided with respect to the third centerline O3.

In some examples, the plurality of first power supply bending lines may be symmetrically provided with respect to the third centerline O3. The first group of first power supply bending lines 321 may be symmetrically provided with respect to the third centerline O3. A quantity of first power supply bending lines in the second group of first power supply bending lines 322 and a quantity of first power supply bending lines in the third group of first power supply bending lines 323 may be the same, and the second group of first power supply bending lines 322 and the third group of first power supply bending lines 323 may be symmetrically provided with respect to the third centerline O3. A quantity of first power supply bending lines in the fourth group of first power supply bending lines 324 and a quantity of first power supply bending lines in the fifth group of first power supply bending lines 325 may be the same, and the fourth group of first power supply bending lines 324 and the fifth group of first power supply bending lines 325 may be symmetrically provided with respect to the third centerline O3.

In some examples, a total length of the first group of first power supply bending lines 321 in the second direction X may be greater than a total length of the second group of first power supply bending lines 322 in the second direction X and greater than a total length of the fourth group of first power supply bending lines 324 in the second direction X. The second group of first power supply bending lines 322, the third group of first power supply bending lines 323, the fourth group of first power supply bending lines 324, and the fifth group of first power supply bending lines 325 may have substantially a same total length in the second direction X. However, the present embodiment is not limited thereto. For example, the total lengths of the second group of first power supply bending lines 322 and the third group of first power supply bending lines 323 in the second direction X may be substantially the same, the total lengths of the fourth group of first power supply bending lines 324 and the fifth group of first power supply bending lines 325 in the second direction X may be substantially the same, and the total lengths of the second group of first power supply bending lines 322 and the fourth group of first power supply bending lines 324 in the second direction X may be different. Taking a group of first power supply bending lines including N first power supply bending lines as an example, a total length of the group of first power supply bending lines in the second direction may include a sum of line widths of N first power supply bending lines in the group of first power supply bending lines and lengths of N−1 spacings between adjacent first power supply bending lines.

In some examples, the plurality of second power supply bending lines may be symmetrically provided with respect to the third centerline O3. A quantity of second power supply bending lines in the first group of second power supply bending lines 331 and a quantity of second power supply bending lines in the second group of second power supply bending lines 332 may be the same, and the first group of second power supply bending lines 331 and the second group of second power supply bending lines 332 may be symmetrically provided with respect to the third centerline O3.

In some examples, the plurality of control bending lines may be symmetrically provided with respect to the third centerline O3. A quantity of control bending lines in the first group of control bending lines 341 and a quantity of control bending lines within the second group of control bending lines 342 may be the same, and the first group of control bending lines 341 and the second group of control bending lines 342 may be symmetrically provided with respect to the third centerline O3. In some examples, the control bending lines in the first group of control bending lines 341 or the second group of control bending lines 342 may include effective control bending lines and ineffective control bending lines. When a quantity of effective control bending lines in the first group of control bending lines 341 is different from a quantity of effective control bending lines in the second group of control bending lines 342, ineffective control bending lines may be provided to ensure that quantities of control bending lines in the first group of control bending lines 341 and the second group of control bending lines 342 are the same and that they are arranged symmetrically about the third centerline O3.

In some examples, the third centerline O3 may coincide with the second centerline O2. In other words, the plurality of signal bending lines in the bending area B12 may be symmetrically provided with respect to the second centerline O2.

In some examples, a minimum distance between the first trace edge B121 and the first bezel edge B101 is a first edge distance a, and a minimum distance between the second trace edge B122 and the second bezel edge B102 is a second edge distance b. A ratio of the first edge distance a to the second edge distance b may be 0.9 to 1.1. For example, the first edge distance a may be equal to the second edge distance b. For example, the first edge distance a may be greater than or equal to 0.4 mm, and the second edge distance b may be greater than or equal to 0.4 mm.

In the present example, by symmetrically providing the signal bending lines of the bending area B12 about the second centerline O2, and configuring the first edge distance a and the second edge distance b to be substantially the same, it is possible to reduce wiring difference between a lower left bezel and a lower right bezel, which is beneficial to reduce difference in transmission load of a same signal between the lower left bezel and the lower right bezel.

FIG. 4 is a partially enlarged schematic view of an area S1 in FIG. 3. In FIG. 4, a first group of data bending lines 311, a second group of data bending lines 312, and a first group of first power supply bending lines 321 are schematically illustrated in an integrated manner. In some examples, as shown in FIG. 4, a plurality of data lines in the display area AA may be divided into a first group of data lines DL1a and a second group of data lines DL1b according to the first centerline O1, and a quantity of data lines in the first group of data lines DL1a and a quantity of data lines in the second group of data lines DL1b may be the same. For example, the first group of data lines DL1a and the second group of data lines DL1b may be symmetrically provided with respect to the first centerline O1. For example, the plurality of data lines may be located in a second source-drain metal layer or a third source-drain metal layer.

In some examples, as shown in FIG. 4, the first sub-area B11 may be provided with a plurality of first data fan-out lines. The plurality of first data fan-out lines may include a first group of first data fan-out lines 211 and a second group of first data fan-out lines 212. The first group of first data fan-out lines 211 may be connected to the first group of data lines DLa, and the second group of first data fan-out lines 212 may be connected to the second group of data lines DLb. The first group of first data fan-out lines 211 may include a plurality of first data fan-out lines 21a, and the plurality of first data fan-out lines 21a may be electrically connected to a plurality of data lines in the first group of data lines DLa in a one-to-one correspondence. The second group of first data fan-out lines 212 may include a plurality of first data fan-out lines 21b, and the plurality of second data fan-out lines 21b may be electrically connected to a plurality of data lines in the second group of data lines DLb in one-to-one correspondence. For example, a plurality of first data fan-out lines may be alternately arranged on a first gate metal layer and a second gate metal layer, and orthographic projections of adjacent first data fan-out lines on the base substrate may not overlap.

In some examples, a first data fan-out line 21a may include a first data extension segment 21-1a and a second data extension segment 21-2a connected to each other. The second data extension segment 21-2a may be connected to at least one data bending line in a group of data bending lines (e.g., the first group of data bending lines 311). The first data extension segment 21-2a may be located on a side of the second data extension segment 21-2a close to the display area AA. The second data extension segment 21-2a may be a straight line segment extending in the first direction Y, and an extension direction of the first data extension segment 21-1a may intersect the first direction Y. For example, the first data extension segment 21-1a may be an oblique line segment, an extension direction of which intersects both the first direction Y and the second direction X.

In some examples, a first data fan-out line 21b may include a first data extension segment 21-1b and a second data extension segment 21-2b connected to each other. The second data extension segment 21-2b may be connected to at least one data bending line in a group of data bending lines (e.g., the second group of data bending lines 312). The first data extension segment 21-1b may be located on a side of the second data extension segment 21-2b close to the display area AA. The second data extension segment 21-2b may be a straight line segment extending in the first direction Y, and an extension direction of the first data extension segment 21-1b may intersect the first direction Y. For example, the first data extension segment 21-1b may be an oblique line segment, an extension direction of which intersects both the first direction Y and the second direction X.

In some examples, a length of the first data extension segment 21-1a of at least one first data fan-out line (e.g., the first data fan-out line 21a) close to the first centerline O1 and located on a first side (e.g., a left side) of the first centerline O1 may be greater than a length of the first data extension segment line 21-1b of at least one first data fan-out line (e.g., the first data fan-out line 21b) close to the first centerline O1 and located on a second side (e.g., a right side) of the first centerline O1. A length of the second data extension segment 21-2a of at least one first data fan-out line 21a close to the first centerline O1 may be smaller than a length of the second data extension segment line 21-2b of at least one first data fan-out line 21b close to the first centerline O1. In the present example, by configuring the length of the first data extension segment 21-1a to be greater than the length of the first data extension segment 21-1b, a symmetry centerline of the data bending lines in the bending area B12 may be moved to the first centerline O1 in the opposite direction of the second direction X. For example, the symmetry centerline of the plurality of data bending lines in the bending area B12 (that is, the third centerline O3) may be made to coincide with the second centerline O2.

In some examples, the second sub-area B13 may be provided with a plurality of data lead-out lines. The plurality of data lead-out lines may at least include a first group of data lead-out lines 411 and a second group of data lead-out lines 412. The first group of data lead-out lines 411 may be connected to the first group of data bending lines 311, and the second group of data lead-out lines 412 may be connected to the second group of data bending lines 312. Quantities of data lead-out lines located on two sides of the second centerline O2 may be the same, and the data lead-out lines located on two sides of the second centerline O2 may not be symmetrically provided with respect to the second centerline O2. For example, the plurality of data lead-out lines may be alternately arranged on the first gate metal layer and the second gate metal layer, and orthographic projections of adjacent data lead-out lines on the base substrate may not overlap. However, the present embodiment is not limited thereto. In other examples, the data lead-out lines located on two sides of the second centerline O2 may be symmetrically provided with respect to the second centerline O2.

In the present example, the plurality of signal bending lines in the bending area B12 may be symmetrically provided with respect to the third centerline O3, and the third centerline O3 may coincide with the second centerline O2, thereby ensuring consistency of the signal bending lines in areas on two sides of the second centerline O2 and ensuring bending effect. For example, configuration of the present example may ensure that traces for transmitting a same signal in the bending areas on two sides of the second centerline O2 have a consistent load, thereby avoiding display problems caused by inconsistent signal loads.

In some examples, the plurality of first data fan-out lines in the first sub-area B11 are not symmetrically provided with respect to the second centerline O2, and the plurality of data lead-out lines in the second sub-area B13 are not symmetrically provided with respect to the second centerline O2. A plurality of data contact pads provided in the first signal access area B14 may be symmetrically provided with respect to the second centerline O2, and the plurality of data lead-out lines may be connected to the plurality of data contact pads. For example, the second sub-area B 13 may be provided with a data load compensation structure to achieve uniform load of data signals transmitted by the first bezel area.

In some examples, the second sub-area B13 may include a second fan-out area and a third fan-out area. The plurality of data lead-out lines may include a plurality of second data fan-out lines located in the second fan-out area and a plurality of third data fan-out lines located in the third fan-out area. The data load compensation structure may be located in at least one of the second fan-out area and the third fan-out area of the second sub-area. The data load compensation structure may be connected in series with the data lead-out lines in the second sub-area. For example, the data load compensation structure may be located in the second fan-out area and connected in series with the second data fan-out lines, or may be located in the third fan-out area and connected in series with the third data fan-out lines. In some examples, the data load compensation structure may be a serpentine trace, increasing resistance by increasing lengths of the data lead-out lines. The serpentine trace is a bending curve. For example, after one end of the line extends in one direction for a certain distance, it bends circuitously and extends in a direction opposite to this direction for a certain distance, and bends circuitously again and extends in this direction. In this way, circuitous bending is repeated for several times to form the serpentine trace.

In other examples, the resistance may be increased by thinning the data lead-out lines in the second sub-area for load compensation. Alternatively, the resistance may be increased for load compensation by adding a quantity of jumpers between a plurality of line segments of the data lead-out lines in the second sub-area. Alternatively, the data lead-out lines in the second sub-area may be provided in a conductive layer having a higher resistivity to increase the resistance.

In other examples, the resistance may be reduced by increasing line widths of the data lead-out lines in the second sub-area for load compensation. Alternatively, the resistance may be reduced by providing the data lead-out lines in the second sub-area as double-layer or multi-layer traces. Alternatively, the data lead-out lines in the second sub-area may be provided in a conductive layer having a lower resistivity to reduce the resistance. The present embodiment does not limit the load compensation method of the data signal in the first bezel area.

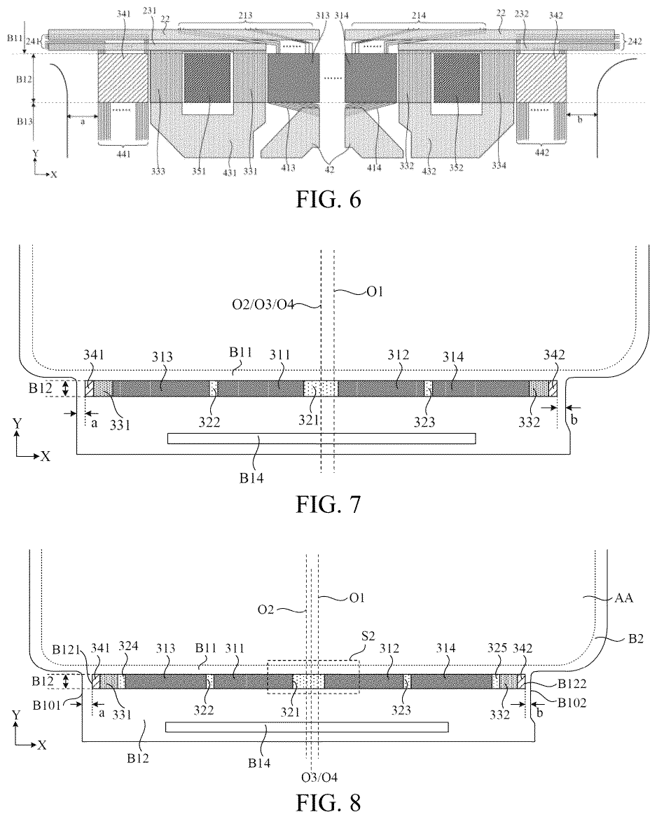

FIG. 5 is another schematic partial structural view of a first bezel area according to at least one embodiment of the present disclosure. FIG. 6 is a schematic diagram of partial traces in a first bezel area according to at least one embodiment of the present disclosure. In FIGS. 5 and 6, each group of data bending lines, each group of first power supply bending lines, each group of second power supply bending lines, each group of control bending lines, and each group of touch bending lines in the bend region B12 are schematically illustrated in an integrated manner.

In some examples, as shown in FIGS. 5 and 6, the bending area B12 may be provided with four groups of data bending lines (including, for example, a first group of data bending lines 311, a second group of data bending lines 312, a third group of data bending lines 313, and a fourth group of data bending lines 314), three groups of first power supply bending lines (including, for example, a first group of first power supply bending lines 321, a second group of first power supply bending lines 322, and a third group of first power supply bending lines 323), four groups of second power supply bending lines (including, for example, a first group of second power supply bending lines 331, a second group of second power supply bending lines 332, a third group of second power supply bending lines 333 and a fourth group of second power supply bending lines 334), two groups of control bending lines (including, for example, a first group of control bending lines 341 and a second group of control bending lines 342), and two groups of touch bending lines (including, for example, a first group of touch bending lines 351 and a second group of touch bending lines 352). The plurality of signal bending lines in the bending area B12 may have a fourth centerline O4 extending in the first direction Y. The fourth centerline O4 may coincide with the third centerline O3. The plurality of signal bending lines in the bending area B12 may be symmetrically provided with respect to the third centerline O3, and the third centerline O3 may coincide with the second centerline O2.

In some examples, the first group of control bending lines 341, the third group of second power supply bending lines 333, the first group of touch bending lines 351, the first group of second power supply bending lines 331, the third group of data bending lines 313, the second group of first power supply bending lines 322, the first group of data bending lines 311, the first group of first power supply bending lines 321, the second group of data bending lines 312, the third group of first power supply bending lines 323, the fourth group of data bending lines 314, the second group of second power supply bending lines 332, the second group of touch bending lines 351, the fourth group of second power supply bending lines 334, and the second group of control bending lines 342 may be sequentially arranged in the second direction X.

In some examples, as shown in FIG. 6, the first sub-area B11 may be provided with a plurality of first data fan-out lines, a first peripheral power supply line 22, second peripheral power supply lines 231 and 232, and a plurality of peripheral control lines (including, for example, a first group of peripheral control lines 241 and a second group of peripheral control lines 242). The plurality of first data fan-out lines may include a first group of first data fan-out lines, a second group of first data fan-out lines, a third group of first data fan-out lines 213, and a fourth group of first data fan-out lines 214. The third group of first data fan-out lines 213, the first group of first data fan-out lines, the second group of first data fan-out lines, and the fourth group of first data fan-out lines 214 may be sequentially arranged in the second direction X. The first group of first data fan-out lines may be connected to the first group of data bending lines 311, the second group of first data fan-out lines may be connected to the second group of data bending lines 312, the third group of first data fan-out lines 213 may be connected to the third group of data bending lines 313, and the fourth group of first data fan-out lines 214 may be connected to the fourth group of data bending lines 314. For example, the plurality of first data fan-out lines may be alternately arranged in the first gate metal layer and the second gate metal layer, or may all be located in the first gate metal layer, or may all be located in the second gate metal layer.

In some examples, the first peripheral power supply line 22 may be a single-layer trace located in the first source-drain metal layer, or may be a single-layer trace located in the second source-drain metal layer, or may be a double-layer trace located in the first source-drain metal layer and the second source-drain metal layer. The first peripheral power supply line 22 may include a first power supply main body portion extending in the second direction X and a plurality of first power supply connection portions (for example, three first connection portions) extending in the first direction Y. The three first power connection portions may be electrically connected to three groups of first power supply bending lines (including, for example, a first group of first power supply bending lines 321, a second group of first power supply bending lines 322, and a third group of first power supply bending lines 323) in one-to-one correspondence. For example, a first power supply connection portion and a group of first power supply bending lines correspondingly connected thereto may be an interconnected integral structure. In some examples, the first peripheral power supply line 22 may be substantially symmetrical about the third centerline O3.

In some examples, the second peripheral power supply lines 231 and 232 may be located on a side of the first power supply main body portion of the first peripheral power supply line 22 away from the display area AA. The second peripheral power supply line 231 may extend toward the second bezel area B2, and the second peripheral power supply line 232 may extend toward the third bezel area B3. The second peripheral power supply line 231 may be located on one side of the third centerline O3, and the second peripheral power supply line 232 may be located on the other side of the third centerline O3. For example, the second peripheral power supply lines 231 and 232 may be substantially symmetrical about the third centerline O3. The second peripheral power supply line 231 may be connected to the first group of second power supply bending lines 331 and the third group of second power supply bending lines 333. The second peripheral power supply line 232 may be connected to the second group of second power supply bending lines 332 and the fourth group of second power supply bending lines 334. In some examples, the second peripheral power supply lines 231 and 232 may be single-layer traces located in the first source-drain metal layer, or may be single-layer traces located in the second source-drain metal layer, or may be double-layer traces located in the first source-drain metal layer and the second source-drain metal layer.

In some examples, the first group of peripheral control lines 241 may be located on one side of the third centerline O3, and the second group of peripheral control lines 242 may be located on the other side of the third centerline O3. The first group of peripheral control lines 241 may extend toward the second bezel area B2, and the second group of peripheral control lines 242 may extend toward the third bezel area B3. The first group of peripheral control lines 241 may be connected to the first group of control bending lines 341, and the second group of peripheral control lines 242 may be connected to the second group of control bending lines 342. The plurality of peripheral control lines may be located on a side of the second peripheral power supply lines 231 and 232 close to the base substrate, for example, may be located in the first gate metal layer or the second gate metal layer.

In some examples, the second sub-area B13 may be provided with a first power supply lead-out line 42, second power supply lead-out lines 431 and 432, a plurality of control lead-out lines (including, for example, a first group of control lead-out lines 441 and a second group of control lead-out lines 442), and a plurality of data lead-out lines (including, for example, a first group of data lead-out lines, a second group of data lead-out lines, a third group of data lead-out lines 413, and a fourth group of data lead-out lines 414). The third group of data lead-out lines 413, the first group of data lead-out lines, the second group of data lead-out lines, and the fourth group of data lead-out lines 414 may be arranged in the second direction X. The first group of data lead-out lines may be connected to the first group of data bending lines 311, the second group of data lead-out lines may be connected to the second group of data bending lines 312, the third group of data lead-out lines 413 may be connected to the third group of data bending lines 313, and the fourth group of data lead-out lines 414 may be connected to the fourth group of data bending lines 314. The first group of data bending lines 311 may realize electrical connection between the first group of first data fan-out lines and the first group of data lead-out lines, the second group of data bending lines 312 may realize electrical connection between the second group of first data fan-out lines and the second group of data lead-out lines, the third group of data bending lines 313 may realize electrical connection between the third group of first data fan-out lines and the third group of data lead-out lines, and the fourth group of data bending lines 314 may realize electrical connection between the fourth group of first data fan-out lines and the fourth group of data lead-out lines. In some examples, the plurality of data lead-out lines may be alternately arranged in the first gate metal layer and the second gate metal layer, or may all be provided in the first gate metal layer, or may all be provided in the second gate metal layer.

In some examples, as shown in FIGS. 5 and 6, the first power supply lead-out line 42 may include a second power supply main body portion 420 extending in the second direction X, a first power supply extension portion 421 and a second power supply extension portion 422 extending in the first direction Y and located on a side of the second power supply main body 420 away from the bending area B12, and a plurality of second power supply connection portions (including, for example, three second power supply connection portions) extending in the second direction Y and located on a side of the second power supply main body portion 420 close to the bending area B12. The second power supply main body portion 420, the first power supply extension portion 421, the second power supply extension portion 422, and the plurality of power supply connection portions may be of an interconnected integral structure. For example, the first power supply lead-out line 42 may be substantially symmetrical about the third centerline O3. The first power supply extension portion 421 is connected to one end of the power supply main body portion 420 in the first direction X, and the second power supply extension portion 422 is connected to the other end of the power supply main body portion 420 in the first direction X. The first power supply extension portion 421 may bypass the first signal access area B14 from one side (for example, a left side) of the first signal access area B14 in the opposite direction of the second direction X, and extend to a second signal access area B15 to be connected to a second contact pad within the second signal access area B15. The second power supply extension portion 422 may bypass the first signal access area B14 from the other side (for example, a right side) of the first signal access area B14 in the second direction X, and extend to the second signal access area B15 to be connected to a second contact pad within the second signal access area B15. The three second power supply connection portions may be electrically connected to the first group of first power supply bending lines 321, the second group of first power supply bending lines 322, and the third group of first power supply bending lines 323 in a one-to-one correspondence to realize electrical connection with the first peripheral power supply line 22 in the first sub-area B11. In some examples, the first power supply lead-out line 42 may be a single-layer trace located in the first source-drain metal layer, or may be a single-layer trace located in the second source-drain metal layer, or may be a double-layer trace located in the first source-drain metal layer and the second source-drain metal layer.

In some examples, the second power supply lead-out line 431 may be located on a side of the first power supply lead-out line 42 in the opposite direction of the second direction X, and the second power supply lead-out line 432 may be located one a side of the first power supply lead-out line 42 in the second direction X. The second power supply lead-out line 431 may be connected to the first group of second power supply bending lines 331 and the third group of second power supply bending lines 333 to achieve electrical connection with the second peripheral power line 231 in the first sub-area B11. The second power lead-in line 432 may be connected to the second group of second power supply lead-out lines 332 and the fourth group of second power supply lead-out lines 334 to achieve electrical connection with the second peripheral power line 232 in the first sub-area B11. For example, the second power supply lead-out line 431 and the second power supply lead-out line 432 may be substantially symmetrical about the third centerline O3. In some examples, the second power supply lead-out lines 431 and 432 may be single-layer traces located in the first source-drain metal layer, or may be single-layer traces located in the second source-drain metal layer, or may be double-layer traces located in the first source-drain metal layer and the second source-drain metal layer.

In some examples, the first power supply lead-out line 42 is configured to transmit a first voltage signal, and the second power supply lead-out lines 431 and 432 is configured to transmit a second voltage signal. The first voltage signal is different from the second voltage signal. For example, the first voltage signal may be greater than the second voltage signal. The first voltage signal may be configured to be provided to a pixel circuit of a sub-pixel of the display area, and the second voltage signal may be configured to be provided to a cathode of a light emitting element of a sub-pixel of the display area. The present embodiment is not limited thereto.

In some examples, the first group of control lead-out lines 441 may be connected to the first group of control bending lines 341 to realize electrical connection with the first group of peripheral control lines 241 within the first sub-area B11. The second group of control lead-out lines 442 may be connected to the second group of control bending lines 342 to realize electrical connection with the second group of peripheral control lines 242 within the first sub-area B11. The plurality of control lead-out lines may include a trace that supplies a signal (e.g., a start signal, a clock signal, a voltage signal, etc.) to the gate drive circuit, a trace that transmits a panel test signal, and the like.

The signal bending lines of the bending area B12 in the present example may be symmetrically provided with respect to the third centerline O3, the third centerline O3 may coincide with the second centerline O2, and the first edge distance a and the second edge distance b are substantially the same, which may ensure consistency in density and film layer of the traces in the bending area B12 on two sides of the second centerline O2, thereby ensuring bending performance. The present example may ensure consistency in load of signals transmitted by the first group of control bending lines 341 and the second group of control bending lines 342, and avoid display problems caused by inconsistent signal loads on two sides. The present example may also ensure consistency in transmission load of the first voltage signal and the second voltage signal on two sides of the second centerline. The present example may also ensure that the space in the first bezel area is utilized to the maximum extent. Rest of a structure of the first bezel area of the present example may be referred to the description of the aforementioned embodiments, which will not be repeated here.

FIG. 7 is another partial view of a first bezel area according to at least one embodiment of the present disclosure. In some examples, as shown in FIG. 7, the bending area B12 may be provided with four groups of data bending lines (for example, a first group of data bending lines 311, a second group of data bending lines 312, a third group of data bending lines 313, and a fourth group of data bending lines 314), three groups of first power supply bending lines (for example, a first group of first power supply bending lines 321, a second group of first power supply bending lines 322, and a third group of first power supply bending lines 323), two groups of second power supply bending lines (for example, a first group of second power supply bending lines 331 and a second group of second power supply bending lines 332), and two groups of control bending lines (for example, a first group of control bending lines 341 and a second group of control bending lines 342).

In some examples, the first group of control bending lines 341, the first group of second power supply bending lines 331, the third group of data bending lines 313, the second group of first power supply bending lines 322, the first group of data bending lines 311, the first group of first power supply bending lines 321, the second group of data bending lines 312, the third group of first power supply bending lines 323, the fourth group of data bending lines 314, the second group of second power supply bending lines 332, and the second group of control bending lines 342 may be sequentially provided in the second direction X.

In some examples, the first group of data bending lines 311 and the second group of data bending lines 312 may be symmetrically provided with respect to the third centerline O3, the second group of data bending lines 313 and the fourth group of data bending lines 314 may be symmetrically provided with respect to the third centerline O3, the first group of first power supply bending lines 321 may be symmetrically provided with respect to the third centerline O3, the second group of first power supply bending lines 322 and the third group of first power supply bending lines 323 may be symmetrically provided with respect to the third centerline O3, the first group of second power supply bending lines 331 and the second group of second power supply bending lines 332 may be symmetrically provided with respect to the third centerline O3, and the first group of control bending lines 341 and the second group of control bending lines 342 may be symmetrically provided with respect to the third centerline O3.

In some examples, the fourth centerline O4 coincides with the third centerline O3. The third centerline O3 may coincide with the second centerline O2. The first edge distance a and the second edge distance b may be substantially the same. In the present example, by symmetrically providing a group of signal bending lines of the bending area B12 about the second centerline O2, and configuring the first edge distance a and the second edge distance b to be substantially the same, it is possible to reduce wiring difference between a lower left bezel and a lower right bezel, which is beneficial to reduce difference in transmission load of a same signal between the lower left bezel and the lower right bezel.

Rest of description about the first bezel area of the present example may be referred to the description of the aforementioned embodiments, which will not be repeated here.

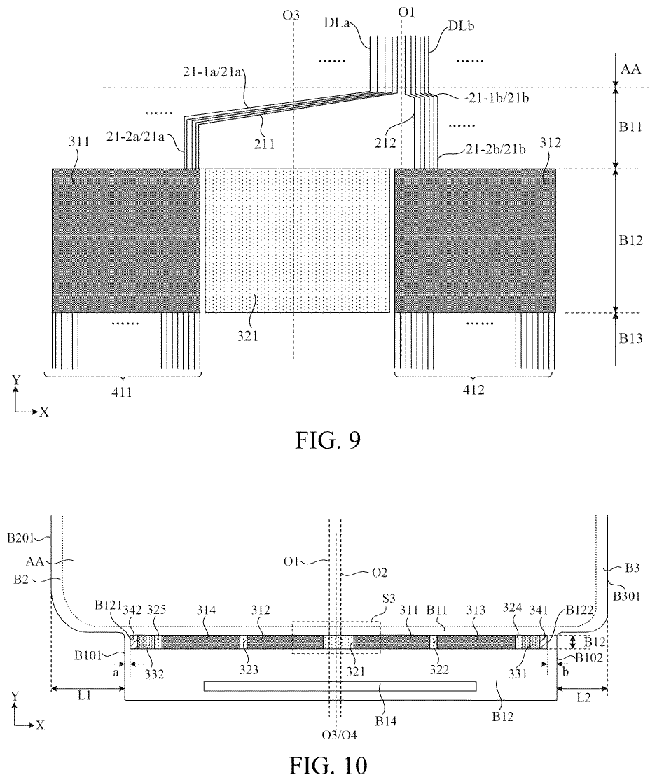

FIG. 8 is another partial view of a first bezel area according to at least one embodiment of the present disclosure. FIG. 9 is a partially enlarged schematic view of an area S2 in FIG. 8. In some examples, as shown in FIGS. 8 and 9, the plurality of signal bending lines in the bending area B12 may include four groups of data bending lines (including, for example, a first group of data bending lines 311, a second group of data bending lines 312, a third group of data bending lines 313, and a fourth group of data bending lines 314), five groups of first power supply bending lines (including, for example, a first group of first power supply bending lines 321, a second group of first power supply bending lines 322, a third group of first power supply bending lines 323, a fourth group of first power supply bending lines 324, and a fifth group of first power supply bending lines 325), two groups of second power supply bending lines (including, for example, a first group of second power supply bending lines 331 and a second group of second power supply bending lines 332), and two groups of control bending lines (including, for example, a first group of control bending lines 341 and a second group of control bending lines 342).

In some examples, as shown in FIG. 8, the first group of control bending lines 342, the first group of second power supply bending lines 331, the fourth group of first power supply bending lines 324, the third group of data bending lines 313, the second group of first power supply bending lines 322, the first group of data bending lines 311, the first group of first power supply bending lines 321, the second group of data bending lines 313, the third group of first power supply bending lines 323, the fourth group of data bending lines 314, the fifth group of first power supply bending lines 325, the second group of second power supply bending lines 332, and the second group of control bending lines 342 may be sequentially arranged in the second direction X.

In some examples, the plurality of signal bending lines of the bending area B12 may have a fourth centerline O4 extending in the first direction Y, and the fourth centerline O4 may coincide with the third centerline O3. For example, the plurality of signal bending lines may be symmetrically provided with respect to the third centerline O3. An orthographic projection of traces of the bending area B12 on the base substrate may have a first trace edge B121 and a second trace edge B122 extending in the first direction Y. The first trace edge B121 may be a left edge of the traces, and the second trace edge B122 may be a right edge of the traces. A distance between the third centerline O3 and the first trace edge B121 and a distance between the third centerline O3 and the second trace edge B122 may be the same.

In some examples, a distance between the third centerline O3 and the second centerline O2 in the second direction X may be greater than 0. The third centerline O3 may not coincide with the second centerline O2. For example, the third centerline O3 may be located in a middle between the second centerline O2 and the first centerline O1. A distance between the third centerline O3 and the first centerline O1 and a distance between the third centerline O3 and the second centerline O2 may be the same or different. The first centerline O1 may be located on a side of the second centerline O2 in the second direction X. However, the present embodiment is not limited thereto. In other examples, the third centerline O3 may coincide with the first centerline O1.

In some examples, a minimum distance between the first trace edge B121 and the first bezel edge B101 is a first edge distance a, and a minimum distance between the second trace edge and the second bezel edge B102 is a second edge distance b. The first edge distance a may be different from the second edge distance b. For example, a ratio of the first edge distance a to the second edge distance b may be greater than 1. In other words, the first edge distance a may be greater than the second edge distance b. The first edge distance a may be greater than or equal to 0.4 mm, and the second edge distance b may be greater than or equal to 0.4 mm.

In some examples, as shown in FIG. 9, the first sub-area B11 may be provided with a plurality of first data fan-out lines. The plurality of first data fan-out lines may include a first group of first data fan-out lines 211 and a second group of first data fan-out lines 212. The first group of first data fan-out lines 211 may be connected to the first group of data lines DLa, and the second group of first data fan-out lines 212 may be connected to the second group of data lines DLb. The first group of first data fan-out lines 211 may include a plurality of first data fan-out lines 21a, and the plurality of first data fan-out lines 21a may be electrically connected to a plurality of data lines in the first group of data lines DLa in a one-to-one correspondence. The second group of first data fan-out lines 212 may include a plurality of first data fan-out lines 21b, and the plurality of second data fan-out lines 21b may be electrically connected to a plurality of data lines in the second group of data lines DLb in one-to-one correspondence.

In some examples, a first data fan-out line 21a may include a first data extension segment 21-1a and a second data extension segment 21-2a connected to each other. The second data extension segment 21-2a may be connected to at least one data bending line in a group of data bending lines (e.g., the first group of data bending lines 311). The first data extension segment 21-2a may be located on a side of the second data extension segment 21-2a close to the display area AA. The second data extension segment 21-2a may be a straight line segment extending in the first direction Y, and an extension direction of the first data extension segment 21-1a may intersect the first direction Y. For example, the first data extension segment 21-1a may be an oblique line segment, an extension direction of which intersects both the first direction Y and the second direction X.

In some examples, a first data fan-out line 21b may include a first data extension segment 21-1b and a second data extension segment 21-2b connected to each other. The second data extension segment 21-2b may be connected to at least one data bending line in a group of data bending lines (e.g., the second group of data bending lines 312). The first data extension segment 21-1b may be located on a side of the second data extension segment 21-2b close to the display area AA. The second data extension segment 21-2b may be a straight line segment extending in the first direction Y, and an extension direction of the first data extension segment 21-1b may intersect the first direction Y. For example, the first data extension segment 21-1b may be an oblique line segment, an extension direction of which intersects both the first direction Y and the second direction X.

In some examples, a length of the first data extension segment 21-1a of at least one first data fan-out line 21a close to the first centerline O1 may be greater than a length of the first data extension segment line 21-1b of at least one first data fan-out line 21b close to the first centerline O1. A ratio of a length of the first data extension segment 21-1a of the first data fan-out line 21a to a length of the first data extension segment 21- b of the first data fan-out line 21b in the present example may be smaller than a ratio of a length of the first data extension segment 21-1a of the first data fan-out line 21a to a length of the first data extension segment 21-b of the first data fan-out line 21b in the embodiment shown in FIG. 4, which may reduce difference in load between first data fan-out lines on two sides of the first centerline O1.

In the present example, the traces in the bending area B12 may be substantially symmetrically provided with respect to the third centerline O3. By adjusting the first edge distance a and the second edge distance b (for example, the first edge distance a is greater than the second edge distance b), the third centerline O3 may be located between the second centerline O2 and the first centerline O1, so as to reduce difference in load between the first data fan-out lines in the first sub-area B11, thereby facilitating compensation of the data signal, and facilitating realization of consistency in load of the data signal. The present example may reduce wiring difference between the lower left bezel and the lower right bezel, which is beneficial to reduce difference in transmission load of a same signal between the lower left bezel and the lower right bezel. Rest of description of the present example may be referred to the description of the aforementioned embodiments, which will not be repeated here.

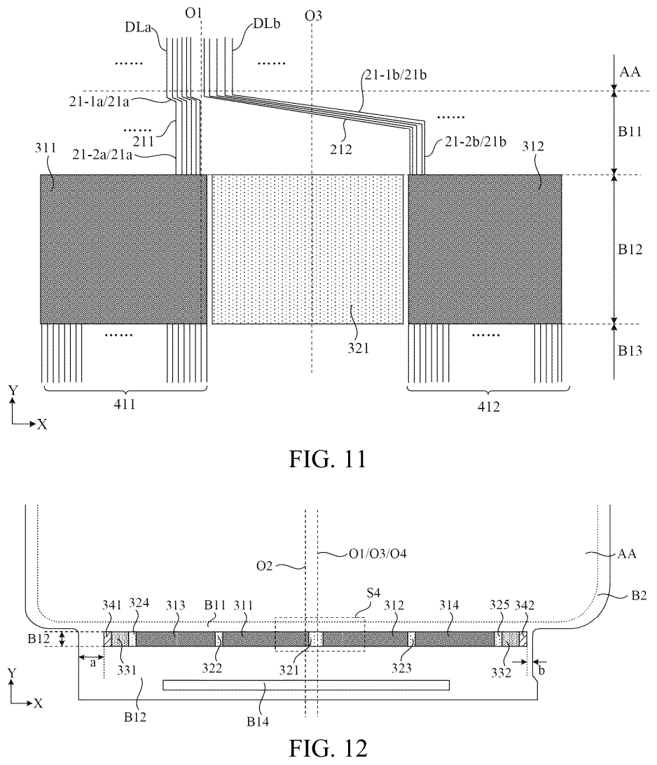

FIG. 10 is another partial view of a first bezel area according to at least one embodiment of the present disclosure. FIG. 11 is a partially enlarged schematic view of an area S3 in FIG. 10. In some examples, as shown in FIGS. 10 and 11, the first distance L1 may be greater than the second distance L2, and the first centerline O2 may be located on a side of the first centerline O1 in the second direction X. Traces on a left side of the third centerline O3 and traces on a right side of the third centerline O3 in the bending area B12 may be arranged substantially symmetrically. The third centerline O3 may be located in the middle between the first centerline O1 and the second centerline O2. The fourth centerline O4 may coincide with the third centerline O3.

In some examples, a ratio of the second edge distance b to the first edge distance a may be greater than 1. In other words, the second edge distance b may be greater than the first edge distance a.

In some examples, a length of the first data extension segment 21-1a of at least one first data fan-out line 21a close to the first centerline O1 may be smaller than a length of the first data extension segment line 21-1b of at least one first data fan-out line 21b close to the first centerline O1. A length of the second data extension segment 21-2a of at least one first data fan-out line 21a close to the first centerline O1 may be greater than a length of the second data extension segment line 21-2b of at least one first data fan-out line 21b close to the first centerline O1.

In the present example, the traces in the bending area B12 may be substantially symmetrically provided with respect to the third centerline O3. By adjusting the first edge distance a and the second edge distance b (for example, the second edge distance b is greater than the first edge distance a), the third centerline O3 may be located between the second centerline O2 and the first centerline O1 (or may coincide with the first centerline O1), so as to reduce difference in load between the first data fan-out lines in the first sub-area B11, thereby facilitating compensation of the data signal, and facilitating realization of consistency in load of the data signal. The present example may reduce wiring difference between the lower left bezel and the lower right bezel, which is beneficial to reduce difference in transmission load of a same signal between the lower left bezel and the lower right bezel. Rest of description of the present example may be referred to the description of the aforementioned embodiments, which will not be repeated here.

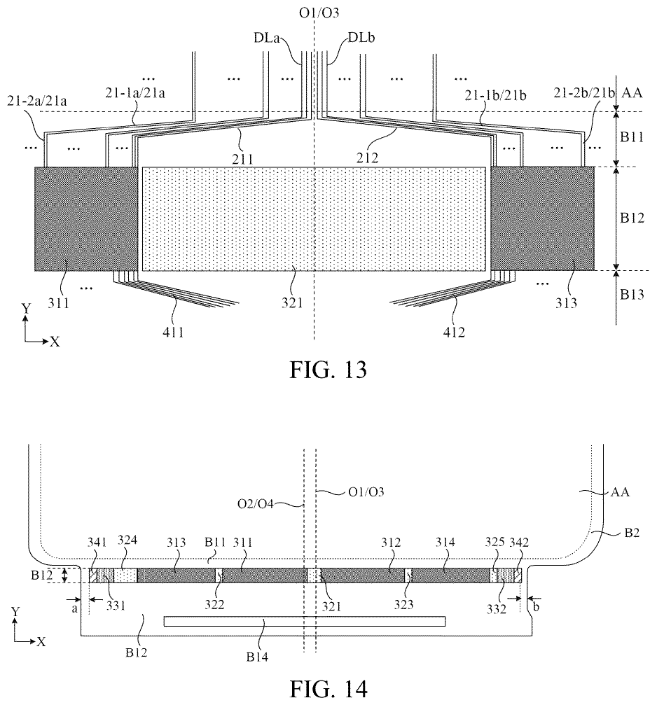

FIG. 12 is another partial view of a first bezel area according to at least one embodiment of the present disclosure. FIG. 13 is a partially enlarged schematic view of an area S4 in FIG. 12. In some examples, as shown in FIGS. 12 and 13, the first centerline O1 may be located on a side of the second centerline O2 in the second direction X. The plurality of signal bending lines in the bending area B12 may include four groups of data bending lines (including, for example, a first group of data bending lines 311, a second group of data bending lines 312, a third group of data bending lines 313, and a fourth group of data bending lines 314), five groups of first power supply bending lines (including, for example, a first group of first power supply bending lines 321, a second group of first power supply bending lines 322, a third group of first power supply bending lines 323, a fourth group of first power supply bending lines 324, and a fifth group of first power supply bending lines 325), two groups of second power supply bending lines (including, for example, a first group of second power supply bending lines 331 and a second group of second power supply bending lines 332), and two groups of control bending lines (including, for example, a first group of control bending lines 341 and a second group of control bending lines 342). The first group of control bending lines 342, the first group of second power supply bending lines 331, the fourth group of first power supply bending lines 324, the third group of data bending lines 313, the second group of first power supply bending lines 322, the first group of data bending lines 311, the first group of first power supply bending lines 321, the second group of data bending lines 313, the third group of first power supply bending lines 323, the fourth group of data bending lines 314, the fifth group of first power supply bending lines 325, the second group of second power supply bending lines 332, and the second group of control bending lines 342 may be sequentially arranged in the second direction X.

In some examples, a total length of the first group of first power supply bending lines 321 in the second direction X may be smaller than a total length of the first group of first power supply bending lines in the second direction X in the embodiment shown in FIG. 8. For example, the total length in the second direction X may be reduced by reducing the quantity of first power supply bending lines in the first group of first power supply bending lines, or the total length in the second direction X may be reduced by reducing the spacing between adjacent first power supply bending lines in the first group of first power supply bending lines, or the length in the second direction X may be reduced by reducing the line width and spacing of the first power supply bending lines in the first group of first power supply bending lines. The present embodiment is not limited thereto.

In some examples, the plurality of signal bending lines in the bending area may have a fourth centerline O4 extending in the first direction Y, and the plurality of signal bending lines may be symmetrically provided with respect to the fourth centerline O4. The fourth centerline O4 may coincide with the third centerline O3, and the third centerline O3 may coincide with the first centerline O1. The plurality of first data fan-out lines in the first sub-area B11 may be symmetrically provided with respect to the first centerline O1. For example, the plurality of first data fan-out lines 21a and the plurality of first data fan-out lines 21b may be symmetrically provided with respect to the first centerline O1. The first group of data lead-out lines 411 and the second group of data lead-out lines 412 may be symmetrically provided with respect to the first centerline O1.

In the present example, by moving the traces in the bending area B12 entirely in the second direction X and reducing the length of the first group of first power supply bending lines in the second direction, combined with adjusting the first edge distance a and the second edge distance b, the third centerline O3 may be made to coincide with the first centerline O1. In the present example, the plurality of first data fan-out lines in the first sub-area B11 may be substantially symmetrical about the first centerline O1, which may ensure consistency in load of the data signal in the first sub-area. In the present example, a group of signal bending lines are symmetrically provided with respect to the first centerline O1, which may be beneficial to reduce wiring difference between the lower left bezel and the lower right bezel, and reduce difference in transmission load of a same signal between the lower left bezel and the lower right bezel. Rest of description of the present example may be referred to the description of the aforementioned embodiments, which will not be repeated here.

FIG. 14 is another partial view of a first bezel area according to at least one embodiment of the present disclosure. In some examples, as shown in FIG. 14, the first centerline O1 may be located on a side of the second centerline O2 in the second direction X. The plurality of signal bending lines in the bending area B12 may include four groups of data bending lines (including, for example, a first group of data bending lines 311, a second group of data bending lines 312, a third group of data bending lines 313, and a fourth group of data bending lines 314), five groups of first power supply bending lines (including, for example, a first group of first power supply bending lines 321, a second group of first power supply bending lines 322, a third group of first power supply bending lines 323, a fourth group of first power supply bending lines 324, and a fifth group of first power supply bending lines 325), two groups of second power supply bending lines (including, for example, a first group of second power supply bending lines 331 and a second group of second power supply bending lines 332), and two groups of control bending lines (including, for example, a first group of control bending lines 341 and a second group of control bending lines 342). The first group of control bending lines 342, the first group of second power supply bending lines 331, the fourth group of first power supply bending lines 324, the third group of data bending lines 313, the second group of first power supply bending lines 322, the first group of data bending lines 311, the first group of first power supply bending lines 321, the second group of data bending lines 313, the third group of first power supply bending lines 323, the fourth group of data bending lines 314, the fifth group of first power supply bending lines 325, the second group of second power supply bending lines 332, and the second group of control bending lines 342 may be sequentially arranged in the second direction X.

In some examples, a length of an orthographic projection of the fourth group of first power supply bending lines 324 on the base substrate in the second direction X may be greater than a length of an orthographic projection of the first group of first power supply bending lines 321 on the base substrate in the second direction X. The length of the orthographic projection of the first group of first power supply bending lines 321 on the base substrate in the second direction X may be greater than lengths of orthographic projections of the second group of first power supply bending lines 322, the third group of first power supply bending lines 323, and the fifth group of first power supply bending lines 325 on the base substrate in the second direction X, respectively.

In some examples, a total length of the fourth group of first power supply bending lines 324 in the second direction X may be increased by at least one of the following methods: increasing the quantity of first power supply bending lines in the fourth group of first power supply bending lines 324, increasing the length of the spacing between adjacent first power supply bending lines in the fourth group of first power supply bending lines 324, and increasing the line width of the first power supply bending lines in the fourth group of first power supply bending lines 324. However, the present embodiment is not limited thereto.

In the present example, the plurality of power supply bending lines in the bending area may include a plurality of first power supply bending lines and a plurality of second power supply bending lines. The first group of power supply bending lines located on one side of the third centerline O3 may include a second group of first power supply bending lines 322, a fourth group of first power supply bending lines 324, half of traces of the first group of first power supply bending lines 321, and a first group of second power supply bending lines 331. The second group of power supply bending lines located on the other side of the third centerline O3 may include a third group of first power supply bending lines 323, a fifth group of first power supply bending lines 325, half of traces of the first group of first power supply bending lines 321, and a second group of second power supply bending lines 332. By increasing the length of the fourth group of first power supply bending lines 324 in the second direction X, a length of the first group of power supply bending lines in the second direction X is made greater than a length of the second group of power supply bending lines in the second direction X. However, the present embodiment is not limited thereto. In other examples, the length of the first group of power supply bending lines in the second direction X may be made greater than the length of the second group of power supply bending lines in the second direction X by increasing a length of the first group of second power supply bending lines 331 in the second direction X.

In some examples, a plurality of data bending lines in the plurality of signal bending lines may be symmetrically provided with respect to a third centerline O3. The plurality of signal bending lines may have a fourth centerline O4 extending in the first direction Y, and the fourth centerline O4 may be located on a side of the third centerline O3 close to the second centerline O2. For example, the fourth centerline O4 may coincide with the second centerline O2. The plurality of signal bending lines may be provided asymmetrically about the fourth centerline O4.

In some examples, the third centerline O3 is a symmetry line of a plurality of groups of data bending lines. The third centerline O3 may coincide with the first centerline O1. For example, the first group of data bending lines 311 and the second group of data bending lines 312 may be substantially symmetrical about the first centerline O1, and the third group of data bending lines 313 and the fourth group of data bending lines 314 may be substantially symmetrical about the first centerline O1. In this way, the plurality of data fan-out lines in the first sub-area B11 may be symmetrically provided with respect to the first centerline O1, thereby reducing difference in load between the first data fan-out lines on two sides of the first centerline O1 in the first sub-area B11, and facilitating realization of consistency in load of the data signal.

In some examples, the first group of control bending lines 341 and the second group of control bending lines 342 are not symmetrically provided with respect to the third centerline O3, and the first group of second power supply bending lines 331 and the second group of second power supply bending lines 332 are not symmetrically provided with respect to the third centerline O3. For example, the first group of control bending lines 341 and the second group of control bending lines 342 may be symmetrically provided with respect to the second centerline O2, and the first group of second power supply bending lines 331 and the second group of second power supply bending lines 332 may be symmetrically provided with respect to the second centerline O2. A ratio of the first edge distance a to the second edge distance b may be 0.9 to 1.1. For example, the first edge distance a and the second edge distance b may be substantially the same. In this way, it is beneficial to improve uniformity in traces in the bending area and ensure the bending effect.

In the present example, by increasing the length of the fourth group of first power supply bending lines 324 in the second direction X, a plurality of groups of data bending lines may be symmetrically provided with respect to the first centerline O1, which may be beneficial to realize consistency in load of the data signal, and allow the first edge distance and the second edge distance to be substantially the same, thereby reducing wiring difference between the lower left bezel and the lower right bezel, and reducing difference in transmission load of a same signal between the lower left bezel and the lower right bezel. Rest of description of the present example may be referred to the description of the aforementioned embodiments, which will not be repeated here.

In other examples, by increasing the lengths of the fourth group of first power supply bending lines and the first group of second power supply bending lines in the second direction, a plurality of groups of data bending lines may be symmetrically provided with respect to the first centerline, and the first edge distance and the second edge distance are substantially the same.

In other examples, by reducing a length of at least one of the fifth group of first power supply bending lines and the second group of second power supply bending lines in the second direction, a plurality of groups of data bending lines may be symmetrically provided with respect to the first centerline, and the first edge distance and the second edge distance are substantially the same.

In other examples, by increasing a length of at least one of the fourth group of first power supply bending lines and the first group of second power supply bending lines in the second direction and by decreasing a length of at least one of the fifth group of first power supply bending lines and the second group of second power supply bending lines in the second direction, a plurality of groups of data bending lines may be symmetrically provided with respect to the first centerline, and the first edge distance and the second edge distance are substantially the same.

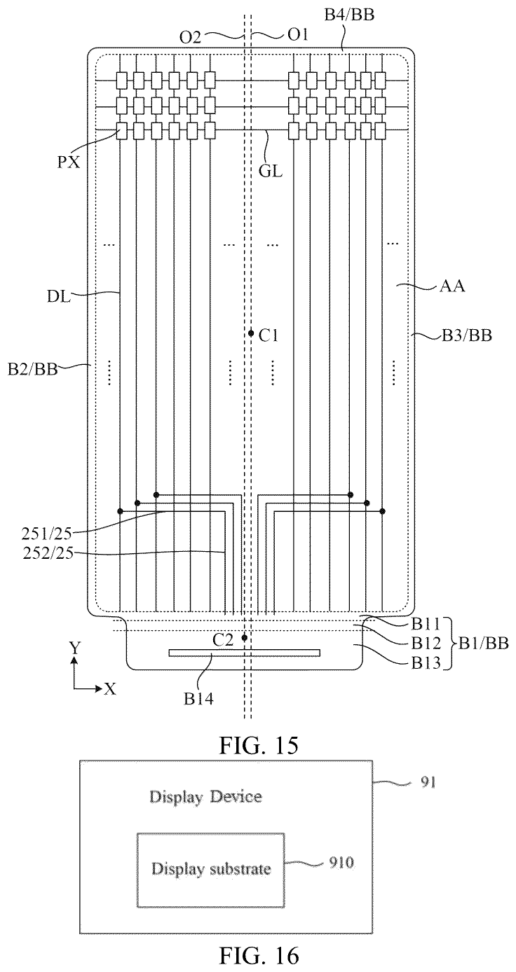

FIG. 15 is another schematic diagram of a display substrate according to at least one embodiment of the present disclosure. In some examples, as shown in FIG. 15, the display area AA may be provided with a plurality of data lines DL and a plurality of data transfer lines 25. At least one data line DL may be connected to a first data fan-out line of the first sub-area B11 via a data transfer line 25. The data transfer line 25 may include a first transfer segment 251 extending in the first direction Y and a second transfer segment 252 extending in the second direction X. The first transfer segment 251 may be connected to a data line DL and a second transfer segment 252, and the second transfer segment 252 may be connected to a first data fan-out line. The second transfer section 252 may be located on a side of the connected data line DL away from an edge of the display substrate. In some examples, the first transfer segment 251 and the second transfer segment 252 may be located in the third source-drain metal layer, and the data line DL may be located in the second source-drain metal layer. However, the present embodiment is not limited thereto. Description about a structure of the first bezel area of the display substrate according to the present example may be referred to the description of the aforementioned embodiments, which will not be repeated here.

An embodiment further provides a display substrate, including a display area and a first bezel area located on a side of the display area in a first direction. The first bezel area includes a bending area, a first sub-area located between the bending area and the display area. The display area has a first centerline extending in the first direction, the first bezel area has a second centerline extending in the first direction, and a distance between the first centerline and the second centerline is greater than 0. The display substrate includes a base substrate, a plurality of sub-pixels and a plurality of data lines provided on a side of the base substrate and located in the display area, a plurality of first data fan-out lines located in the first sub-area, and a plurality of signal bending lines located in the bending area. The plurality of data lines are electrically connected to the plurality of sub-pixels, and configured to provide data signals to the plurality of sub-pixels. The plurality of first data fan-out lines are connected to the plurality of data lines. The plurality of signal bending lines are located in a same conductive layer. The plurality of signal bending lines at least include a plurality of data bending lines. The plurality of data bending lines are connected to the plurality of first data fan-out lines, and the plurality of data bending lines are symmetrically provided with respect to the third centerline. The plurality of signal bending lines have a fourth centerline extending in the first direction, and the fourth centerline coincides with the third centerline, or is located on a side of the third centerline close to the second centerline. Extending directions of the first centerline, the second centerline, the third centerline, and the fourth centerline may be the same.

In the present embodiment, according to the case that the first centerline of the display area and the second centerline of the first bezel area are not in a same straight line, the plurality of data bending lines in the bending area are symmetrically provided with respect to the third centerline, and the fourth centerline of the plurality of signal bending lines in the bending area coincides with the third centerline or is located on a side of the third centerline close to the second centerline, so as to ensure consistency in density and film layer of the data bending lines in the bending area, thereby ensuring bending effect, and mitigating a problem caused by signal trace differences due to asymmetric layout of the display substrate.

In some exemplary embodiments, the plurality of signal bending lines may be symmetrically provided with respect to a fourth centerline. The third centerline and the fourth centerline coincide with the second centerline. The first bezel area has a first bezel edge and a second bezel edge extending in the first direction, the first bezel edge and the second bezel edge are respectively located on two sides of signal bending lines of the bending area in a second direction, and the second direction intersects the first direction. For example, the second direction may be perpendicular to the first direction. A minimum distance between the signal bending lines of the bending area and the first bezel edge is a first edge distance, a minimum distance between the signal bending lines of the bending area and the second bezel edge is a second edge distance, and a ratio of the first edge distance to the second edge distance is 0.9 to 1.1. For example, the first edge distance may be equal to the second edge distance. The present example may ensure consistent distances between the traces of the bending area and edges of two sides of the display substrate, which facilitates arrangement of the traces in the bending area and ensures bending effect.

In some exemplary embodiments, the plurality of signal bending lines may be symmetrically provided with respect to the fourth centerline. The third centerline coincides with the fourth centerline and is located between the first centerline and the second centerline, or the third centerline and the fourth centerline coincide with the first centerline. The first bezel area has a first bezel edge and a second bezel edge extending in the first direction, and the first bezel edge and the second bezel edge are respectively located on two sides of signal bending lines of the bending area in a second direction. A minimum distance between the signal bending lines of the bending area and the first bezel edge is a first edge distance, a minimum distance between the signal bending lines of the bending area and the second bezel edge is a second edge distance, and a ratio of the first edge distance to the second edge distance is greater than 1, or a ratio of the second edge distance to the first edge distance is greater than 1. In other words, the first edge distance is different from the second edge distance. In the present example, by adjusting a difference between the first edge distance and the second edge distance, it is beneficial to ensure symmetrical arrangement of the traces in the bending area, thereby reducing a difference between signals in the first bezel area.

In some exemplary embodiments, the plurality of signal bending lines may be provided asymmetrically about the fourth centerline. The fourth centerline may coincide with the second centerline, and the third centerline may coincide with the first centerline. The first bezel area may have a first bezel edge and a second bezel edge extending in the first direction, and the first bezel edge and the second bezel edge are respectively located on two sides of signal bending lines of the bending area in a second direction. A minimum distance between the signal bending lines of the bending area and the first bezel edge is a first edge distance, a minimum distance between the signal bending lines of the bending area and the second bezel edge is a second edge distance, and a ratio of the first edge distance to the second edge distance is 0.9 to 1.1. For example, the first edge distance may be equal to the second edge distance. The present example may ensure consistent distances between the traces of the bending area and edges of two sides of the display substrate, which facilitates arrangement of the traces in the bending area and ensures bending effect.

Rest of description about the display substrate according to the present example may be referred to the description of the aforementioned embodiments, which will not be repeated here.

FIG. 16 is a schematic diagram of a display device according to at least one embodiment of the present disclosure. In some examples, as shown in FIG. 16, the display device 91 may include a display substrate. The display substrate 910 may be an OLED display substrate. The display device 91 may be any product or component with a display function, such as an OLED display device, a mobile phone, a tablet computer, a television, a monitor, a notebook computer, a digital photo frame, a foldable display screen, an in-vehicle display device, or a navigator. However, the present embodiment is not limited thereto.

In description of the specification, reference terms such as “an embodiment,” “some embodiments”, “an example”, or “some examples” mean that a specific feature, structure, material, or characteristic described in connection with the embodiment or example is included in at least one embodiment or example of the present application. In the specification, schematic expressions of the above terms do not necessarily refer to a same embodiment or example. Moreover, the specific feature, structure, material, or characteristic described may be combined in a proper mode in any one or more embodiments or examples. In addition, if there is no conflict, those skilled in the art may integrate and combine different embodiments or examples and features of different embodiments or examples described in the specification.

Although embodiments of the present application have been shown and described above, it may be understood that the above embodiments are exemplary, but cannot be understood as limitations on the present application. Alterations, modifications, substitutions, and variations to the above embodiments may be made by those skilled in the art within the scope of the present application.

1. A display substrate, comprising a display area and a first bezel area located on a side of the display area in a first direction; wherein the first bezel area comprises a bending area, and a first sub-area located between the bending area and the display area; the display area has a first centerline extending in the first direction, and the first bezel area has a second centerline extending in the first direction; a distance between the first centerline and the second centerline is greater than 0; and
the display substrate further comprises:
a base substrate;
a plurality of sub-pixels provided on a side of the base substrate and located in the display area;
a plurality of data lines located in the display area, wherein the plurality of data lines are electrically connected to the plurality of sub-pixels and configured to provide data signals to the plurality of sub-pixels;
a plurality of first data fan-out lines located in the first sub-area and connected to the plurality of data lines; and
a plurality of data bending lines located in the bending area and connected to the plurality of first data fan-out lines, wherein the plurality of data bending lines are symmetrically provided with respect to a third centerline, and the third centerline coincides with the first centerline, or coincides with the second centerline, or is located between the first centerline and the second centerline.

2. The display substrate according to claim 1, further comprising a plurality of first power supply bending lines located in the bending area and extending in the first direction, wherein the plurality of first power supply bending lines and the plurality of data bending lines are provided at intervals in a second direction, and the second direction intersects the first direction;
the first bezel area further comprises a second sub-area located on a side of the bending area away from the first sub-area; and
the display substrate further comprises a first peripheral power supply line located in the first sub-area and a first power supply lead-out line located in the second sub-area, the first peripheral power supply line and the first power supply lead-out line are connected by the plurality of first power supply bending lines, and the plurality of first power supply bending lines are symmetrically provided with respect to the third centerline.

3. The display substrate according to claim 2, wherein the plurality of data bending lines comprise a first group of data bending lines, a second group of data bending lines, a third group of data bending lines, and a fourth group of data bending lines;
the plurality of first power supply bending lines at least comprise a first group of first power supply bending lines, a second group of first power supply bending lines, and a third group of first power supply bending lines;
the third group of data bending lines, the second group of first power supply bending lines, the first group of data bending lines, the first group of first power supply bending lines, the second group of data bending lines, the third group of first power supply bending lines, and the fourth group of data bending lines are sequentially provided in the second direction; and
the first group of data bending lines and the second group of data bending lines are symmetrically provided with respect to the third centerline, the third group of data bending lines and the fourth group of data bending lines are symmetrically provided with respect to the third centerline, the second group of first power supply bending lines and the third group of first power supply bending lines are symmetrically provided with respect to the third centerline, and the first group of first power supply bending lines are symmetrically provided with respect to the third centerline.

4. The display substrate according to claim 3, wherein a total length of the first group of first power supply bending lines in the second direction is greater than or equal to a total length of the second group of first power supply bending lines in the second direction and greater than or equal to a total length of the third group of first power supply bending lines in the second direction.

5. The display substrate according to claim 3, wherein the plurality of first power supply bending lines further comprise a fourth group of first power supply bending lines and a fifth group of first power supply bending lines, the fourth group of first power supply bending lines are located on a side of the third group of data bending lines away from the second group of first power supply bending lines, and the fifth group of first power supply bending lines are located on a side of the fourth group of data bending lines away from the third group of first power supply bending lines; and the fourth group of first power supply bending lines and the fifth group of first power supply bending lines are symmetrically provided with respect to the third centerline.

6. The display substrate according to claim 2, further comprising a plurality of second power supply bending lines located in the bending area and extending in the first direction, wherein the plurality of second power supply bending lines are located on two sides of the plurality of data bending lines in the second direction;
the display substrate further comprises a second peripheral power supply line located in the first sub-area and a second power supply lead-out line located in the second sub-area; the second peripheral power supply line and the second power supply lead-out line are connected by the plurality of second power supply bending lines, and a second voltage signal transmitted by the second peripheral power supply line is different from a first voltage signal transmitted by the first peripheral power supply line; and the plurality of second power supply bending lines are symmetrically provided with respect to the third centerline.

7. The display substrate according to claim 6, further comprising a plurality of control bending lines located in the bending area and extending in the first direction, wherein the plurality of control bending lines are located on two sides of the plurality of second power supply bending lines in the second direction, and the plurality of control bending lines are symmetrically provided with respect to the third centerline.

8. The display substrate according to claim 1, wherein the third centerline coincides with the second centerline;
the first bezel area has a first bezel edge and a second bezel edge extending in the first direction, the first bezel edge and the second bezel edge are respectively located on two sides of traces of the bending area in the second direction, and the second direction intersects the first direction; and
a minimum distance between the traces of the bending area and the first bezel edge is a first edge distance, a minimum distance between the traces of the bending area and the second bezel edge is a second edge distance, and a ratio of the first edge distance to the second edge distance is 0.9 to 1.1.

9. The display substrate according to claim 1, wherein the third centerline is located between the first centerline and the second centerline, or the third centerline coincides with the first centerline;
the first bezel area has a first bezel edge and a second bezel edge extending in the first direction, the first bezel edge and the second bezel edge are respectively located on two sides of traces of the bending area in the second direction, and the second direction intersects the first direction; and
a minimum distance between the traces of the bending area and the first bezel edge is a first edge distance, a minimum distance between the traces of the bending area and the second bezel edge is a second edge distance, and a ratio of the first edge distance to the second edge distance is greater than 1, or a ratio of the second edge distance to the first edge distance is greater than 1.

10. The display substrate according to claim 1, wherein at least one of the plurality of first data fan-out lines comprises a first data extension segment and a second data extension segment connected to each other; the second data extension segment is connected to at least one of the plurality of data bending lines, the second data extension segment is a straight line segment extending in the first direction, and an extension direction of the first data extension segment intersects the first direction;
the second centerline is located on a first side of the first centerline in a second direction, the second direction intersects the first direction, and the third centerline does not coincide with the first centerline; and
a length of a first data extension segment of at least one first data fan-out line close to the first centerline and located on a first side of the first centerline is greater than a length of a first data extension segment of at least one first data fan-out line close to the first centerline and located on a second side of the first centerline.

11. The display substrate according to claim 1, wherein the third centerline coincides with the first centerline, and the plurality of first data fan-out lines are symmetrically provided with respect to the third centerline.

12. The display substrate according to claim 11, wherein the first bezel area further comprises a second sub-area located on a side of the bending area away from the first sub-area; and
the display substrate further comprises a plurality of data lead-out lines located in the second sub-area, the plurality of data lead-out lines are connected to the plurality of data bending lines, and the plurality of data lead-out lines are symmetrically provided with respect to the third centerline.

13. The display substrate according to claim 1, further comprising a plurality of power supply bending lines located in the bending area, wherein the plurality of power supply bending lines and the plurality of data bending lines are provided at intervals in a second direction, and the second direction intersects the first direction;
the plurality of power supply bending lines comprise a first group of power supply bending lines and a second group of power supply bending lines respectively located on two sides of the third centerline; and
a total length of the first group of power supply bending lines in the second direction is different from a total length of the second group of power supply bending lines in the second direction.

14. The display substrate according to claim 13, wherein the third centerline coincides with the first centerline;
the first bezel area has a first bezel edge and a second bezel edge extending in the first direction, and the first bezel edge and the second bezel edge are respectively located on two sides of traces of the bending area in the second direction; and
a minimum distance between the traces of the bending area and the first bezel edge is a first edge distance, a minimum distance between the traces of the bending area and the second bezel edge is a second edge distance, and a ratio of the first edge distance to the second edge distance is 0.9 to 1.1.

15. The display substrate according to claim 13, wherein the third centerline coincides with the first centerline, the second centerline and the first group of power supply bending lines are located on a same side of the first centerline, and a total length of the first group of power supply bending lines in the second direction is greater than a total length of the second group of power supply bending lines in the second direction.

16. A display device, comprising the display substrate according to claim 1.

17. A display substrate, comprising a display area and a first bezel area located on a side of the display area in a first direction; wherein the first bezel area comprises a bending area, and a first sub-area located between the bending area and the display area; the display area has a first centerline extending in the first direction, and the first bezel area has a second centerline extending in the first direction; a distance between the first centerline and the second centerline is greater than 0; and
the display substrate comprises:
a base substrate;
a plurality of sub-pixels provided on a side of the base substrate and located in the display area;
a plurality of data lines located in the display area, wherein the plurality of data lines are electrically connected to the plurality of sub-pixels and configured to provide data signals to the plurality of sub-pixels;
a plurality of first data fan-out lines located in the first sub-area and connected to the plurality of data lines; and
a plurality of signal bending lines located in the bending area and located in a same conductive layer, wherein the plurality of signal bending lines at least comprise a plurality of data bending lines connected to the plurality of first data fan-out lines, and the plurality of data bending lines are symmetrically provided with respect to a third centerline;
wherein the plurality of signal bending lines have a fourth centerline extending in the first direction, and the fourth centerline coincides with the third centerline, or is located on a side of the third centerline close to the second centerline.

18. The display substrate according to claim 17, wherein the plurality of signal bending lines are symmetrically provided with respect to the fourth centerline, and the third centerline and the fourth centerline coincide with the second centerline;
the first bezel area has a first bezel edge and a second bezel edge extending in the first direction, the first bezel edge and the second bezel edge are respectively located on two sides of signal bending lines of the bending area in a second direction, and the second direction intersects the first direction; and
a minimum distance between the signal bending lines of the bending area and the first bezel edge is a first edge distance, a minimum distance between the signal bending lines of the bending area and the second bezel edge is a second edge distance, and a ratio of the first edge distance to the second edge distance is 0.9 to 1.1.

19. The display substrate according to claim 17, wherein the plurality of signal bending lines are symmetrically provided with respect to the fourth centerline; and the third centerline coincides with the fourth centerline and is located between the first centerline and the second centerline, or the third centerline and the fourth centerline coincide with the first centerline;
the first bezel area has a first bezel edge and a second bezel edge extending in the first direction, the first bezel edge and the second bezel edge are respectively located on two sides of signal bending lines of the bending area in a second direction, and the second direction intersects the first direction; and
a minimum distance between the signal bending lines of the bending area and the first bezel edge is a first edge distance, a minimum distance between the signal bending lines of the bending area and the second bezel edge is a second edge distance, and a ratio of the first edge distance to the second edge distance is greater than 1, or a ratio of the second edge distance to the first edge distance is greater than 1.

20. The display substrate according to claim 17, wherein the plurality of signal bending lines are provided asymmetrically about the fourth centerline, the fourth centerline coincides with the second centerline, and the third centerline coincides with the first centerline;
the first bezel area has a first bezel edge and a second bezel edge extending in the first direction, the first bezel edge and the second bezel edge are respectively located on two sides of signal bending lines of the bending area in a second direction, and the second direction intersects the first direction; and
a minimum distance between the signal bending lines of the bending area and the first bezel edge is a first edge distance, a minimum distance between the signal bending lines of the bending area and the second bezel edge is a second edge distance, and a ratio of the first edge distance to the second edge distance is 0.9 to 1.1.
